(19) United States
(12) Patent Application Publication
(10) Pub. No.: US 2026/0259505 A1
(43) Pub. Date: Sep. 3, 2026

(54) METHOD FOR EFFICIENT DYNAMIC SAMPLING PLAN GENERATION AND ACCURATE PROBE DIE LOSS PROJECTION

(71) Applicant: ASML Netherlands B.V., Veldhoven (NL)

(72) Inventors: Chenxi LIN, Newark, CA (US); Fuming WANG, Santa Clara, CA (US); Zhihuan WANG, Mountain View, CA (US)

(73) Assignee: ASML Netherlands B.V., Veldhoven (NL)

(21) Appl. No.: 19/474,259

(22) PCT Filed: Mar. 14, 2024
(86) PCT No.: PCT/EP2024/056887

§ 371 Date: Oct. 10, 2025

Related U.S. Application Data
(60) Provisional application No. 63/458,625, filed on Apr. 11, 2023.
(60) Provisional application No. 63/465,043, filed on May 9, 2023.

(51) Int. Cl. G03F 7/00

(52) U.S. Cl. CPC G03F 7/705; G03F 7/7065; G03F 7/706833

(57) ABSTRACT

A method to generate an inspection tool sampling plan is disclosed. More, particularly, a method to generate an inspection tool sampling plan for more accurate die loss projection assuming non-uniform defect density or distribution on a wafer is disclosed. A method to optimize an inspection tool sampling plan is disclosed. More particularly, a method of optimizing a wafer region definition and sampling budget distribution for improved die loss projection without relying on pre-determined wafer region definition and sampling budget distribution variables is disclosed. A computational probability prediction model, sampling plan optimizer, and die loss projection formula are disclosed to project die loss with improved accuracy and versatility to guide different wafers for inspection.

### CROSS-REFERENCE TO RELATED APPLICATIONS

This application claims priority of a U.S. application 63/458,625 which was filed on 11 Apr. 2023 and U.S. application 63/465,043, which was filed on 9 May 2023, both of which are incorporated herein in their entireties by reference.

### TECHNICAL FIELD

The embodiments provided herein relate to generating an inspection tool sampling plan, and more particularly to a method to improve die loss projection from an inspection result or optimize a wafer region definition and a sampling budget distribution to project die loss with improved accuracy and without relying on user input (e.g., pre-determined variables).

### BACKGROUND

In manufacturing processes of integrated circuits (ICs), unfinished or finished circuit components are inspected to ensure that they are manufactured according to design and are free of defects. Inspection systems utilizing optical microscopes or charged particle (e.g., electron) beam microscopes, such as a scanning electron microscope (SEM) can be employed. As the physical sizes of IC components continue to shrink, accuracy and yield in defect detection become more important. Various metrology tools are developed and used to check whether the ICs are correctly manufactured. To improve defect inspection performance, a computational guided inspection (CGI) machine learning model may be used to assist the tools by indicating areas of a wafer to be inspected.

### SUMMARY

The embodiments provided herein disclose a method to generate an inspection tool sampling plan, and more particularly, a method of improving die loss projection from an inspection result or optimizing a wafer region definition and sampling budget distribution for improved die loss projection.

Some embodiments provide an apparatus for generating an inspection tool sampling plan comprising a memory storing a set of instructions and at least one processor configured to execute the set of instructions to cause the apparatus to perform a method for generating an inspection tool sampling plan. The method comprises providing input data for a wafer to a computational defect probability prediction model, dividing the wafer into a plurality of wafer regions having dies, determining defective die probabilities per wafer region from the computational defect probability prediction model, selecting at least one die from each wafer region of the plurality of wafer regions using the determined defective die probabilities, and generating a sampling plan for the wafer based on the selected dies.

In some embodiments, an apparatus for optimizing an inspection tool sampling plan comprising a memory storing a set of instructions and at least one processor configured to execute the set of instructions to cause the apparatus to perform a method for optimizing an inspection tool sampling plan is disclosed. The method comprises providing input data for a wafer to a computational defect probability prediction model, and distributing a sampling budget for a region of a wafer based on an expected number of defective die count for the region compared to an expected number of defective die count for the wafer, wherein the expected number of defective die count for the region is a summation of predicted defective die probability for the region and the expected number of defective die count for the wafer is a summation of predicted defective die probability for the wafer, and wherein the predicted defective die probability for the region and the predicted defective die probability for the wafer are obtained from the computational defect probability prediction model.

In some embodiments, an apparatus for optimizing an inspection tool sampling plan comprising a memory storing a set of instructions and at least one processor configured to execute the set of instructions to cause the apparatus to perform a method for optimizing an inspection tool sampling plan is disclosed. The method comprises providing input data for a wafer to a computational defect probability prediction model, determining a defective die probability for each die of the wafer from the computational defect probability prediction model, generating a sampling plan, evaluating a wafer region from the defective die probability for each die of the wafer, evaluating a sampling budget distribution for each evaluated wafer region, and using the sampling plan with the evaluated wafer region and sampling budget distribution to guide wafer inspection of the wafer.

Other advantages of the present disclosure will become apparent from the following description taken in conjunction with the accompanying drawings wherein are set forth, by way of illustration and example, certain embodiments of the present disclosure.

### BRIEF DESCRIPTION OF FIGURES

The above and other aspects of the present disclosure will become more apparent from the description of exemplary embodiments, taken in conjunction with the accompanying drawings.

FIG. 1 is a schematic diagram illustrating an example charged-particle beam inspection system, consistent with embodiments of the present disclosure.

FIG. 2 is a schematic diagram illustrating an example multi-beam tool that can be a part of the example charged-particle beam inspection system of FIG. 1, consistent with embodiments of the present disclosure.

FIG. 3 is a schematic block diagram illustrating throughput to generate input data, consistent with embodiments of the present disclosure.

FIG. 4 is an example flow diagram of a conventional method to project die loss from an inspection result using a sampling plan generated from input data defining a wafer region and a sampling budget per wafer distribution.

FIG. 5 is an example illustration of required input for the empirical sampling plan according to conventional methods.

FIG. 6 is an example flow diagram of a method to generate a dynamic sampling plan for a wafer and projecting die loss from an inspection result according to a non-uniform defect density distribution within a wafer as predicted by a computational model.

FIG. 7 is an example flow diagram of a method to generate a dynamic sampling plan for a wafer without a pre-determined sampling budget distribution per wafer region, consistent with embodiments of the present disclosure.

FIG. 8 is an example sampling plan or estimated defective die probability map, consistent with embodiments of the present disclosure.

FIG. 9 is an example flow diagram of a method to generate a dynamic sampling plan for a wafer without a pre-determined wafer region definition and sampling budget distribution per wafer region, consistent with embodiments of the present disclosure.

FIGS. 10A and 10B are an example estimated defective die probability map used to evaluate a wafer region definition and an example accumulated defective die probability plot, consistent with embodiments of the present disclosure.

FIG. 11 is an example flow diagram of a method to directly optimize a wafer region definition and sampling budget distribution based on the die loss projection R² correlation score, consistent with embodiments of the present disclosure.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations. Instead, they are merely examples of apparatuses and methods consistent with aspects related to the disclosed embodiments as recited in the appended claims. For example, although some embodiments are described in the context of utilizing electron beams, the disclosure is not so limited. Other types of charged-particle beams (e.g., including protons, ions, muons, or any other particle carrying electric charges) may be similarly applied. Furthermore, other imaging systems may be used, such as optical imaging, photon detection, x-ray detection, ion detection, etc.

Electronic devices are constructed of circuits formed on a piece of semiconductor material called a substrate. The semiconductor material may include, for example, silicon, gallium arsenide, indium phosphide, or silicon germanium, or the like. Many circuits may be formed together on the same piece of silicon and are called integrated circuits or ICs. The size of these circuits has decreased dramatically so that many more of them can be fit on the substrate. The enhanced computing power of electronic devices, while reducing the physical size of the devices, can be accomplished by significantly increasing the packing density of circuit components such as transistors, capacitors, diodes, etc. on an IC chip. For example, an IC chip of a smart phone, which is the size of a thumbnail, may include over 2 billion transistors, the size of each transistor being less than 1/1000th of a human hair.

ICs may be manufactured using lithography, which is a fabrication process involving creating complex circuit patterns drawn on a mask deposited onto a substrate. Lithography may be performed by a lithographic apparatus, which is a machine that applies a source of radiation (e.g., light or X-ray) onto a target portion of the substrate to form a desired pattern. The target portion of the substrate may be covered with a pattern device (e.g., mask) that may be either eliminated or developed after exposure to the radiation source. This process of transferring the desired pattern to the substrate is called a patterning process. The patterning process may include a patterning step to transfer a pattern from a pattern device (e.g., a mask) to the substrate. There can also be one or more related pattern processing steps, such as mask development by a development apparatus, baking of the substrate using a bake tool, etching the pattern onto the substrate using an etch apparatus, or other chemical and physical processing steps involved in fabricating a pattern onto the substrate. Variations in experimental parameters (e.g., stochastic variations, errors, or noise due to an inspection tool or pattern processing tool) can potentially limit lithography implementation for high volume manufacturing (HVM), or process yield, of ICs and introduce defects into IC structures.

In the manufacture of ICs using a lithographic apparatus, typically many lithographic patterning steps are performed, thereby forming functional features in successive layers on the substrate. A critical aspect of performance of the lithographic apparatus is therefore the ability to place the applied pattern correctly and accurately in relation to features laid down in previous layers. For this purpose, the substrate is provided with one or more sets of alignment marks. Each mark is a structure having a position that can be measured later using, for example, an electron beam inspection tool. Defects may occur in which an applied pattern structure or pattern layer is incorrectly placed in relation to a reference mark, or when the fabrication conditions are suboptimal. A reference mark or layout define the desired structure, structure dimensions, and the distance between IC structures (such as gates, capacitors, etc.) or interconnect lines. This may ensure that the IC devices or lines do not interact with one another in an undesirable way. The structure limitations provided by the reference layouts are typically referred to as critical dimensions. A critical dimension of a circuit can be defined as the smallest width of a line or hole or the smallest space between two lines or two holes. Thus, the critical dimension determines the overall size and packing density of the designed IC. A goal in IC fabrication is to faithfully reproduce the original IC design on the substrate. If an error occurs during fabrication where the created IC design pattern does not match the reference design, this may result in a defect in the IC structure and render the IC inoperable.

Making these ICs with extremely small structures or components is a complex, time-consuming, and expensive process, often involving hundreds of individual steps. Errors in even one step have the potential to dramatically affect the function of the final product. Even one “killer defect” can cause device failure. The goal of the manufacturing process is to improve the overall yield of the process. For example, for a 50-step process to get to a 75% yield, each individual step must have a yield greater than 99.4%, and if the individual step yield is 95%, the overall process yield drops to 7%.

While high process yield is desirable in an IC chip manufacturing facility, maintaining a high wafer throughput, defined as the number of wafers processed per hour, is also essential. High process yields and high wafer throughput can be impacted by the presence of defects, especially if operator intervention is required for reviewing the defects. Thus, high throughput detection and identification of micro and nano-sized defects is desired. One component of improving process yield and wafer throughput may be monitoring the IC fabrication process to ensure a desired number of defect-free ICs are produced. One way to monitor the fabrication process is to inspect the chip circuit structures at various stages of fabrication. Inspection using tools such as, for example, a charged particle beam inspection tool may be used to this effect to maintain high process yield and high wafer throughput. Inspection of a wafer using an electron beam inspection tool may generate images of the wafer to measure IC structure dimensions. The measured dimensions may be compared to a reference structure absent any defects to determine the presence of defects in the imaged structure. If the structure is defective, then the fabrication process can be adjusted, so the defect is less likely to recur. However, as wafer may contain up to 1 billion IC structures, inspection of ICs for defect detection is often a time-consuming process and may not inspect a wafer at a correct location to identify a defect.

To mitigate the limitations of inspection of ICs for defect detection of an entire wafer, conventional methods have been applied to estimate, or project, a total number of defective die on a wafer at the end of production using inspection results of a wafer during HVM. The total number of defective die on a wafer is referred to as the die loss per wafer. Conventional methods rely on an empirical or fixed sampling plan to guide inspection for each wafer inspected during HVM. The sampling plan is a two-dimensional map of a wafer indicating where a particular defective die may be located. Conventional methods use historical inspection results identifying defective die from previously inspected wafers to generate the sampling plan. The sampling plan is divided into wafer regions, where each wafer region has a determined number of die to inspect (e.g., a sampling budget). Wafer inspection may occur in-line with wafer fabrication and each wafer that is inspected during wafer fabrication is inspected according to this sampling plan. After obtaining inspection results for a wafer using the empirical and fixed sampling plan, the die loss for the wafer at the end of production is projected with the assumption that the defect density or distribution within each wafer region is uniform. The projected die loss may be used to confirm a satisfactory wafer yield is maintained throughout manufacturing and to estimate the failure rate, or actual die loss per wafer, at the end of production. Wafer processing continues until a batch of wafers are fully fabricated, and then the actual die loss is measured by applying a probe test to the fabricated wafer in the batch. A final metric to evaluate the accuracy of the conventional method may be to determine the R² correlation score between the projected die loss per wafer and the actual die loss per wafer.

However, the conventional method described above may limit the accuracy of projecting die loss per wafer from inspection results. Using a fixed sampling plan to guide inspection for every wafer inspected during HVM may not be responsive to wafer to wafer variation that occurs during wafer processing. This may therefore not be optimal regarding efficiently capturing defective die in each wafer inspected. The conventional method to project die loss also assumes a uniform defect density or distribution within each wafer, which may not accurately reflect actual defect density or distribution within a wafer. Furthermore, the wafer regions and sampling budget assigned to each wafer region may not be optimal in the fixed sampling plan to ensure a high defect capture rate for each wafer inspected. Thus, the conventional method using a fixed sampling plan to guide inspection and assuming a uniform defect density or distribution may not accurately predict defective die for a wafer during HVM.

Embodiments of the present disclosure may provide a model-based method to generate a defect probability estimate based on incoming wafer metrology data to generate a dynamic sampling plan. The dynamic sampling plan may be used to guide inspection of a wafer during HVM. In some embodiments, the present disclosure may provide a method to more accurately project die loss without assuming a uniform defect density or distribution within a wafer using a model-based scaling factor. In some embodiments, the present disclosure may provide a method to optimize a wafer region definition or a sampling budget distribution per wafer region without a pre-determined value from input data. Some embodiments of the present disclosure may provide a model-based method for optimizing a sampling budget distribution for a wafer region using a pre-determined wafer region. Some embodiments of the present disclosure may provide a model-based method to optimize a wafer region and a sampling budget per wafer region without a pre-determined value from input data. Some embodiments of the present disclosure may also provide an optimization-based method to directly optimize parameterized wafer region and sampling budget per wafer region variables by optimizing a defective die projection R² correlation score. Some embodiments of the present disclosure may provide a method to improve performance and versatility of a computational model to guide wafer inspection. Some embodiments of the present disclosure may provide a method to increase defect inspection accuracy and yield of defect-free wafers throughout HVM.

Relative dimensions of components in drawings may be exaggerated for clarity. Within the following description of drawings, the same or like reference numbers refer to the same or like components or entities, and only the differences with respect to the individual embodiments are described. As used herein, unless specifically stated otherwise, the term “or” encompasses all possible combinations, except where infeasible. For example, if it is stated that a component may include A or B, then, unless specifically stated otherwise or infeasible, the component may include A, or B, or A and B. As a second example, if it is stated that a component may include A, B, or C, then, unless specifically stated otherwise or infeasible, the component may include A, or B, or C, or A and B, or A and C, or B and C, or A and B and C.

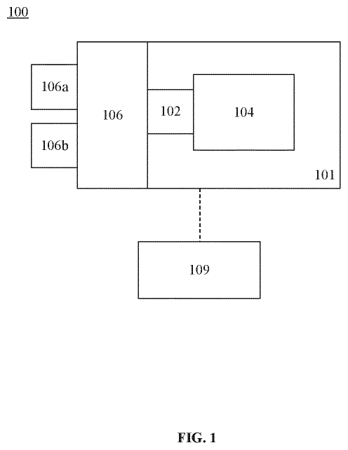

FIG. 1 illustrates an example electron beam inspection (EBI) system 100 consistent with embodiments of the present disclosure. EBI system 100 may be used for imaging. As shown in FIG. 1, EBI system 100 includes a main chamber 101, a load/lock chamber 102, a beam tool 104, and an equipment front end module (EFEM) 106. Beam tool 104 is located within main chamber 101. EFEM 106 includes a first loading port 106a and a second loading port 106b. EFEM 106 may include additional loading port(s). First loading port 106a and second loading port 106b receive wafer front opening unified pods (FOUPs) that contain wafers (e.g., semiconductor wafers or wafers made of other material(s)) or samples to be inspected (wafers and samples may be used interchangeably). A “lot” is a plurality of wafers that may be loaded for wafer processing as a batch.

One or more robotic arms (not shown) in EFEM 106 may transport the wafers to load/lock chamber 102. Load/lock chamber 102 is connected to a load/lock vacuum pump system (not shown) which removes gas molecules in load/lock chamber 102 to reach a first pressure below the atmospheric pressure. After reaching the first pressure, one or more robotic arms (not shown) may transport the wafer from load/lock chamber 102 to main chamber 101. Main chamber 101 is connected to a main chamber vacuum pump system (not shown) which removes gas molecules in main chamber 101 to reach a second pressure below the first pressure. After reaching the second pressure, the wafer is subject to inspection by beam tool 104. Beam tool 104 may be a single-beam system or a multi-beam system.

A controller 109 is electronically connected to beam tool 104. Controller 109 may be a computer configured to execute various controls of EBI system 100. While controller 109 is shown in FIG. 1 as being outside of the structure that includes main chamber 101, load/lock chamber 102, and EFEM 106, it is appreciated that controller 109 may be a part of the structure.

In some embodiments, controller 109 may include one or more processors (not shown). A processor may be a generic or specific electronic device capable of manipulating or processing information. For example, the processor may include any combination of any number of a central processing unit (or “CPU”), a graphics processing unit (or “GPU”), an optical processor, a programmable logic controller, a microcontroller, a microprocessor, a digital signal processor, an intellectual property (IP) core, a Programmable Logic Array (PLA), a Programmable Array Logic (PAL), a Generic Array Logic (GAL), a Complex Programmable Logic Device (CPLD), a Field-Programmable Gate Array (FPGA), a System On Chip (SoC), an Application-Specific Integrated Circuit (ASIC), and any type circuit capable of data processing. The processor may also be a virtual processor that includes one or more processors distributed across multiple machines or devices coupled via a network.

In some embodiments, controller 109 may further include one or more memories (not shown). A memory may be a generic or specific electronic device capable of storing codes and data accessible by the processor (e.g., via a bus). For example, the memory may include any combination of any number of a random-access memory (RAM), a read-only memory (ROM), an optical disc, a magnetic disk, a hard drive, a solid-state drive, a flash drive, a security digital (SD) card, a memory stick, a compact flash (CF) card, or any type of storage device. The codes and data may include an operating system (OS) and one or more application programs (or “apps”) for specific tasks. The memory may also be a virtual memory that includes one or more memories distributed across multiple machines or devices coupled via a network.

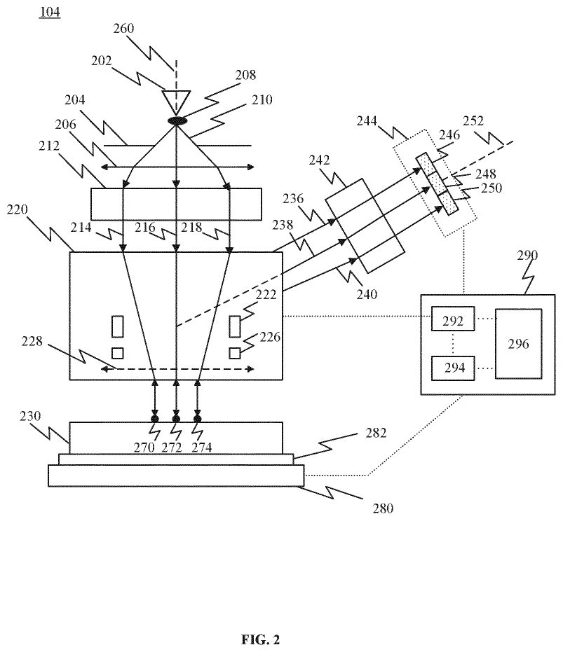

FIG. 2 illustrates a schematic diagram of an example multi-beam tool 104 (also referred to herein as apparatus 104) and an image processing system 290 that may be configured for use in EBI system 100 (FIG. 1), consistent with embodiments of the present disclosure.

Beam tool 104 comprises a charged-particle source 202, a gun aperture 204, a condenser lens 206, a primary charged-particle beam 210 emitted from charged-particle source 202, a source conversion unit 212, a plurality of beamlets 214, 216, and 218 of primary charged-particle beam 210, a primary projection optical system 220, a motorized wafer stage 280, a wafer holder 282, multiple secondary charged-particle beams 236, 238, and 240, a secondary optical system 242, and a charged-particle detection device 244. Primary projection optical system 220 can comprise a beam separator 222, a deflection scanning unit 226, and an objective lens 228. Charged-particle detection device 244 can comprise detection sub-regions 246, 248, and 250.

Charged-particle source 202, gun aperture 204, condenser lens 206, source conversion unit 212, beam separator 222, deflection scanning unit 226, and objective lens 228 can be aligned with a primary optical axis 260 of apparatus 104. Secondary optical system 242 and charged-particle detection device 244 can be aligned with a secondary optical axis 252 of apparatus 104.

Charged-particle source 202 can emit one or more charged particles, such as electrons, protons, ions, muons, or any other particle carrying electric charges. In some embodiments, charged-particle source 202 may be an electron source. For example, charged-particle source 202 may include a cathode, an extractor, or an anode, wherein primary electrons can be emitted from the cathode and extracted or accelerated to form primary charged-particle beam 210 (in this case, a primary electron beam) with a crossover (virtual or real) 208. For ease of explanation without causing ambiguity, electrons are used as examples in some of the descriptions herein. However, it should be noted that any charged particle may be used in any embodiment of this disclosure, not limited to electrons. Primary charged-particle beam 210 can be visualized as being emitted from crossover 208. Gun aperture 204 can block off peripheral charged particles of primary charged-particle beam 210 to reduce Coulomb effect. The Coulomb effect may cause an increase in size of probe spots.

Source conversion unit 212 can comprise an array of image-forming elements and an array of beam-limit apertures. The array of image-forming elements can comprise an array of micro-deflectors or micro-lenses. The array of image-forming elements can form a plurality of parallel images (virtual or real) of crossover 208 with a plurality of beamlets 214, 216, and 218 of primary charged-particle beam 210. The array of beam-limit apertures can limit the plurality of beamlets 214, 216, and 218. While three beamlets 214, 216, and 218 are shown in FIG. 2, embodiments of the present disclosure are not so limited. For example, in some embodiments, the apparatus 104 may be configured to generate a first number of beamlets. In some embodiments, the first number of beamlets may be in a range from 1 to 1000. In some embodiments, the first number of beamlets may be in a range from 200-500. In an exemplary embodiment, the apparatus 104 may generate 400 beamlets.

Condenser lens 206 can focus primary charged-particle beam 210. The electric currents of beamlets 214, 216, and 218 downstream of source conversion unit 212 can be varied by adjusting the focusing power of condenser lens 206 or by changing the radial sizes of the corresponding beam-limit apertures within the array of beam-limit apertures. Objective lens 228 can focus beamlets 214, 216, and 218 onto a wafer 230 for imaging, and can form a plurality of probe spots 270, 272, and 274 on a surface of wafer 230.

Beam separator 222 can be a beam separator of Wien filter type generating an electrostatic dipole field and a magnetic dipole field. In some embodiments, if they are applied, the force exerted by the electrostatic dipole field on a charged particle (e.g., an electron) of beamlets 214, 216, and 218 can be substantially equal in magnitude and opposite in a direction to the force exerted on the charged particle by magnetic dipole field. Beamlets 214, 216, and 218 can, therefore, pass straight through beam separator 222 with zero deflection angle. However, the total dispersion of beamlets 214, 216, and 218 generated by beam separator 222 can also be non-zero. Beam separator 222 can separate secondary charged-particle beams 236, 238, and 240 from beamlets 214, 216, and 218 and direct secondary charged-particle beams 236, 238, and 240 towards secondary optical system 242.

Deflection scanning unit 226 can deflect beamlets 214, 216, and 218 to scan probe spots 270, 272, and 274 over a surface area of wafer 230. In response to the incidence of beamlets 214, 216, and 218 at probe spots 270, 272, and 274, secondary charged-particle beams 236, 238, and 240 may be emitted from wafer 230. Secondary charged-particle beams 236, 238, and 240 may comprise charged particles (e.g., electrons) with a distribution of energies. For example, secondary charged-particle beams 236, 238, and 240 may be secondary electron beams including secondary electrons (energies≤50 eV) and backscattered electrons (energies between 50 eV and landing energies of beamlets 214, 216, and 218). Secondary optical system 242 can focus secondary charged-particle beams 236, 238, and 240 onto detection sub-regions 246, 248, and 250 of charged-particle detection device 244. Detection sub-regions 246, 248, and 250 may be configured to detect corresponding secondary charged-particle beams 236, 238, and 240 and generate corresponding signals (e.g., voltage, current, or the like) used to reconstruct an SCPM image of structures on or underneath the surface area of wafer 230.

The generated signals may represent intensities of secondary charged-particle beams 236, 238, and 240 and may be provided to image processing system 290 that is in communication with charged-particle detection device 244, primary projection optical system 220, and motorized wafer stage 280. The movement speed of motorized wafer stage 280 may be synchronized and coordinated with the beam deflections controlled by deflection scanning unit 226, such that the movement of the scan probe spots (e.g., scan probe spots 270, 272, and 274) may orderly cover regions of interests on the wafer 230. The parameters of such synchronization and coordination may be adjusted to adapt to different materials of wafer 230. For example, different materials of wafer 230 may have different resistance-capacitance characteristics that may cause different signal sensitivities to the movement of the scan probe spots.

The intensity of secondary charged-particle beams 236, 238, and 240 may vary according to the external or internal structure of wafer 230, and thus may indicate whether wafer 230 includes defects. Moreover, as discussed above, beamlets 214, 216, and 218 may be projected onto different locations of the top surface of wafer 230, or different sides of local structures of wafer 230, to generate secondary charged-particle beams 236, 238, and 240 that may have different intensities. Therefore, by mapping the intensity of secondary charged-particle beams 236, 238, and 240 with the areas of wafer 230, image processing system 290 may reconstruct an image that reflects the characteristics of internal or external structures of wafer 230.

In some embodiments, image processing system 290 may include an image acquirer 292, a storage 294, and a controller 296. Image acquirer 292 may comprise one or more processors. For example, image acquirer 292 may comprise a computer, server, mainframe host, terminals, personal computer, any kind of mobile computing devices, or the like, or a combination thereof. Image acquirer 292 may be communicatively coupled to charged-particle detection device 244 of beam tool 104 through a medium such as an electric conductor, optical fiber cable, portable storage media, IR, Bluetooth, internet, wireless network, wireless radio, or a combination thereof. In some embodiments, image acquirer 292 may receive a signal from charged-particle detection device 244 and may construct an image. Image acquirer 292 may thus acquire SCPM images of wafer 230. Image acquirer 292 may also perform various post-processing functions, such as generating contours, superimposing indicators on an acquired image, or the like. Image acquirer 292 may be configured to perform adjustments of brightness and contrast of acquired images. In some embodiments, storage 294 may be a storage medium such as a hard disk, flash drive, cloud storage, random access memory (RAM), other types of computer-readable memory, or the like. Storage 294 may be coupled with image acquirer 292 and may be used for saving scanned raw image data as original images, and post-processed images. Image acquirer 292 and storage 294 may be connected to controller 296. In some embodiments, image acquirer 292, storage 294, and controller 296 may be integrated together as one control unit.

In some embodiments, image acquirer 292 may acquire one or more SCPM images of a wafer based on an imaging signal received from charged-particle detection device 244. An imaging signal may correspond to a scanning operation for conducting charged particle imaging. An acquired image may be a single image comprising a plurality of imaging areas. The single image may be stored in storage 294. The single image may be an original image that may be divided into a plurality of regions. Each of the regions may comprise one imaging area containing a feature of wafer 230. The acquired images may comprise multiple images of a single imaging area of wafer 230 sampled multiple times over a time sequence. The multiple images may be stored in storage 294. In some embodiments, image processing system 290 may be configured to perform image processing steps with the multiple images of the same location of wafer 230.

In some embodiments, image processing system 290 may include measurement circuits (e.g., analog-to-digital converters) to obtain a distribution of the detected secondary charged particles (e.g., secondary electrons). The charged-particle distribution data collected during a detection time window, in combination with corresponding scan path data of beamlets 214, 216, and 218 incident on the wafer surface, can be used to reconstruct images of the wafer structures under inspection. The reconstructed images can be used to reveal various features of the internal or external structures of wafer 230, and thereby can be used to reveal any defects that may exist in the wafer.

In some embodiments, the charged particles may be electrons. When electrons of primary charged-particle beam 210 are projected onto a surface of wafer 230 (e.g., probe spots 270, 272, and 274), the electrons of primary charged-particle beam 210 may penetrate the surface of wafer 230 for a certain depth, interacting with particles of wafer 230. Some electrons of primary charged-particle beam 210 may elastically interact with (e.g., in the form of elastic scattering or collision) the materials of wafer 230 and may be reflected or recoiled out of the surface of wafer 230. An elastic interaction conserves the total kinetic energies of the bodies (e.g., electrons of primary charged-particle beam 210) of the interaction, in which the kinetic energy of the interacting bodies does not convert to other forms of energy (e.g., heat, electromagnetic energy, or the like). Such reflected electrons generated from elastic interaction may be referred to as backscattered electrons (BSEs). Some electrons of primary charged-particle beam 210 may inelastically interact with (e.g., in the form of inelastic scattering or collision) the materials of wafer 230. An inelastic interaction does not conserve the total kinetic energies of the bodies of the interaction, in which some or all of the kinetic energy of the interacting bodies convert to other forms of energy. For example, through the inelastic interaction, the kinetic energy of some electrons of primary charged-particle beam 210 may cause electron excitation and transition of atoms of the materials. Such inelastic interaction may also generate electrons exiting the surface of wafer 230, which may be referred to as secondary electrons (SEs). Yield or emission rates of BSEs and Ses depend on, e.g., the material under inspection and the landing energy of the electrons of primary charged-particle beam 210 landing on the surface of the material, among others. The energy of the electrons of primary charged-particle beam 210 may be imparted in part by its acceleration voltage (e.g., the acceleration voltage between the anode and cathode of charged-particle source 202 in FIG. 2). The quantity of BSEs and Ses may be more or fewer (or even the same) than the injected electrons of primary charged-particle beam 210.

The images generated by SCPM may be used for defect inspection. For example, a generated image capturing a test device region of a wafer may be compared with a reference image capturing the same test device region. The reference image may be predetermined (e.g., by simulation) and include no known defect. If a difference between the generated image and the reference image exceeds a tolerance level, a potential defect may be identified. For another example, the SCPM may scan multiple regions of the wafer, each region including a test device region designed as the same, and generate multiple images capturing those test device regions as manufactured. The multiple images may be compared with each other. If a difference between the multiple images exceeds a tolerance level, a potential defect may be identified.

Although reference may be made in the present disclosure to ICs, it is appreciated that the present disclosure may be applicable to other possible applications or designs. For example, the present disclosure may be applied to integrated optical systems, magnetic domain memories, liquid-crystal display panels, thin-film magnetic heads, and other nanoscale structures. It is further appreciated that the terms “die”, “structure”, and “IC structure” are used interchangeably in this disclosure.

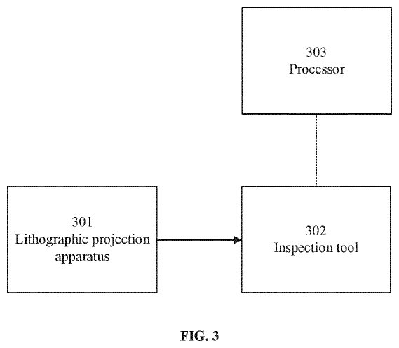

Reference is now made to FIG. 3, which is an example block diagram for generating input data, consistent with embodiments of the present disclosure. Input data may be generated using two steps as illustrated in FIG. 3. A lithographic projection apparatus 301 may be used to fabricate a wafer at a constant fabrication condition (e.g., a focus and dose for a radiation source). An inspection tool 302 (e.g., EBI system 100 in FIG. 1 or multi-beam tool 104 in FIG. 2) may be used to measure metrology information of structures formed on the wafer that was generated by lithographic projection apparatus 301. Metrology information may include, but is not limited to, necking, line pull back, line thinning, critical dimension, edge placement, overlapping, resist top loss, resist undercut, missing defects, and bridging defects of an IC structure on a wafer. A processor 303 (e.g., controller 109 in FIG. 1) with a memory may be communicatively connected to inspection tool 302 to store the measured metrology information.

The images generated by inspection tool 302 may be used for wafer inspection. For example, a generated image capturing a test device region of a wafer may be compared with a reference image capturing the same test device region. The reference image may be predetermined (e.g., by simulation) and include no known defect. If a difference between the generated image and the reference image exceeds a tolerance level, a potential defect may be identified. For another example, inspection tool 302 may scan multiple regions of the wafer, each region including a test device region designed as the same and generate multiple images capturing those test device regions as manufactured. The multiple images may be compared with each other. If a difference between the multiple images exceeds a tolerance level, a potential defect may be identified.

In some embodiments, processor 303 may be a generic or specific electronic device capable of manipulating or processing information. For example, processor 303 may include any combination of any number of a central processing unit (or “CPU”), a graphics processing unit (or “GPU”), an optical processor, a programmable logic controller, a microcontroller, a microprocessor, a digital signal processor, an intellectual property (IP) core, a Programmable Logic Array (PLA), a Programmable Array Logic (PAL), a Generic Array Logic (GAL), a Complex Programmable Logic Device (CPLD), a Field-Programmable Gate Array (FPGA), a System On Chip (SoC), an Application-Specific Integrated Circuit (ASIC), and any type circuit capable of data processing. Processor 303 may also be a virtual processor that includes one or more processors distributed across multiple machines or devices coupled via a network.

In some embodiments, processor 303 may further include one or more memories (not shown).

A memory may be a generic or specific electronic device capable of storing codes and data accessible by the processor (e.g., via a bus). For example, the memory may include any combination of any number of a random-access memory (RAM), a read-only memory (ROM), an optical disc, a magnetic disk, a hard drive, a solid-state drive, a flash drive, a security digital (SD) card, a memory stick, a compact flash (CF) card, or any type of storage device. The codes and data may include an operating system (OS) and one or more application programs (or “apps”) for specific tasks. The memory may also be a virtual memory that includes one or more memories distributed across multiple machines or devices coupled via a network.

Current projection methods to estimate defective die formation during wafer processing and

project die loss at the end of wafer processing rely on using an empirical and fixed sampling plan for wafer inspection. The sampling plan may be generated by compiling historical inspection results that identify certain locations of wafer defects. The conventional sampling plan is also used for each wafer that is inspected during wafer processing and is thus considered “fixed” or “static.” Once an inspection result for a wafer is obtained via the conventional sampling plan, the projected die loss may be calculated via the following equations:

$$Number of estimated defective dies within wafer zone = \frac{{N}_{dd}^{identified}}{{N}_{d}^{inspected}} * {N}_{d} \qquad ( Equation 1 )$$

$$Projected die loss = {\sum }_{i = 1}^{M} Number of estimated defective dies within wafer zone \qquad ( Equation 2 )$$

In equation 1,

$${N}_{dd}^{identified}$$

is the number of defective dies identified,

$${N}_{d}^{inspected}$$

is the number of dies inspected, and Nais the number of dies within a wafer zone. Since the conventional method assumes the defect density or distribution within a wafer region, or zone, is uniform

$${N}_{dd}^{identified}$$

may be multiplied by a scaling factor. According to Equation 1, the scaling factor may be considered to be the ratio of N_{d} to

$${N}_{dd}^{identified}$$

which may scale up

$${N}_{d}^{inspected} ,$$

to estimate the number of defective dies for the entire wafer zone. In Equation 2, the summation is from 1 wafer region up to M wafer regions, where M is an integer.

In addition to the assuming defect density or distribution within a wafer region is uniform, conventional methods require a pre-determined wafer region definition and sampling budget per wafer region distribution in the sampling plan. However, this may limit the accuracy of the projected die loss (e.g., a suboptimal R² correlation score) since defect density or distribution may not be uniform within a wafer region and the pre-determined wafer region definition and sampling budget per wafer region distribution may be highly empirical. Moreover, conventional methods maintain the same wafer region definition and sampling budget distribution per wafer region for all incoming wafers. This may limit the versatility of the conventional method to accurately project the die loss in a variety of wafers, since each wafer may have differences in optimal wafer region definitions or a sampling budget per wafer region. This may result in the sampling plan inaccurately guiding inspection of wafers during HVM such that defects are missed and thus project an inaccurate die loss (e.g., a suboptimal R² correlation score). This would therefore decrease defect-free wafer yield and throughput during HVM.

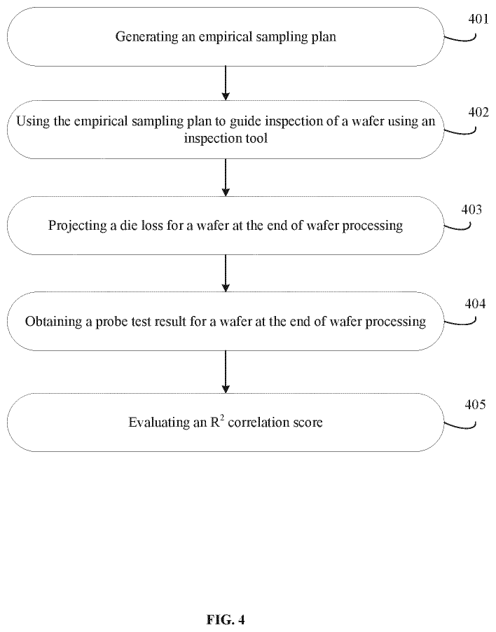

Reference is now made to FIG. 4, which is an example flow diagram of a conventional method to project die loss for a wafer according to inspection results collected from an empirical static (e.g., constant from wafer to wafer) sampling plan with a fixed wafer region definition and sampling budget per wafer region distribution. The steps of FIG. 4 may be performed by a computing device and an inspection tool.

In step 401, an empirical sampling plan is generated. The sampling plan may be generated based on historical data from a previously inspected wafer or a batch of previously inspected wafers. The historical data may be inspection images that contain identified defects on a wafer. Thus, the generated sampling plan may include this historical defect signature. Furthermore, the sampling plan is generated according to a pre-determined wafer region definition and sampling budget per wafer region.

In step 402, the empirical sampling plan is used to guide inspection of a wafer using an inspection tool. Wafer inspection is conducted according to the pre-determined sampling budget for each wafer region in the sampling plan. Wafer inspection is conducted in-line with HVM. The number of dies inspected in a first wafer region is equal to the sampling budget for the first wafer region, and the same is true for a second wafer region.

In step 403, the die loss for a wafer is projected for a wafer at the end of wafer processing using the obtained inspection results. The die loss projection may be performed as described above in Equation 1 and Equation 2 (e.g., assumes that defect density or distribution within a wafer region is uniform).

In step 404, the actual die loss is obtained by applying a probe test to a wafer at the end of wafer processing. The probe test determines if each die on a wafer is defective or not. In step 405, a R² correlation score is evaluated from the actual die loss and the projected die loss. It is appreciated that the R² correlation score may be determined from a population of wafers. A first wafer and a second wafer may be inspected according to step 402 and two projected die loss values may be determined according to step 403. The first wafer and the second wafer at the end of wafer processing may be measured according to step 404 to obtain two actual die loss values.

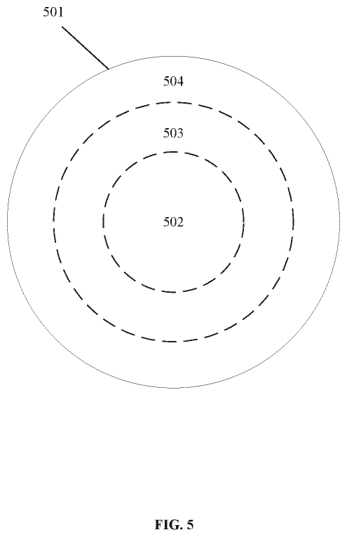

Reference is now made to FIG. 5, which is an example illustration of required input for the empirical sampling plan according to conventional methods. FIG. 5 illustrates a wafer 501 with a first wafer region 502, a second wafer region 503, and a third wafer region 504. Each wafer region has a corresponding sampling budget. Each wafer region definition and corresponding sampling budget per wafer region may not be adjusted according to conventional methods. Furthermore, each wafer region definition is kept constant for each wafer inspected.

Following conventional methods to generate an empirical sampling plan with a pre-determined wafer region definition and sampling budget distribution per wafer region may result in inaccurately guiding inspection of a wafer and decreasing inspection yield throughput. Furthermore, relying on a constant wafer region definition and sampling budget distribution per wafer region for all incoming wafers and assuming defect density distribution within a wafer region is uniform may make it challenging to accurately project die loss for different wafers during HVM and thus ensure desirable wafer yield is maintained.

Embodiments of the present disclosure may provide a model-based approach to project die loss during wafer processing. Computational guided inspection (CGI) processes guide inspection tools to locations on a wafer where there is a higher probability of defects. A machine learning-based CGI model receives input from various data sources, such as wafer characteristic data (which may include scanner data, metrology data, and fabrication process data) to train the model with inspection results. A CGI machine learning model may be built and used to output a sampling plan indicating a location on a wafer where defects have likely formed after a wafer processing step, so the inspection tool will go to the sampling location to inspect with a higher efficiency than inspecting wafer locations based on experience (e.g., a history of prior defects detected during scanning). The CGI process occurs in-line with wafer fabrication and increases inspection tool efficiency by increasing the accuracy of finding defects on the wafer with capture rates of finding defects higher than a baseline value. The inspection results may be used to confirm a satisfactory wafer yield is maintained throughout manufacturing and to project the failure rate, or die loss per wafer, at the end of production. This projected failure rate may be compared to the results of a wafer probe test, which determines a failure rate for each die fabricated on the wafer. A final metric of a CGI model use case may be the R² correlation score between the estimated and measured die defects for a wafer.

A CGI model may be applied to characteristic wafer data to estimate a defect probability for each die on a wafer. A sampling plan optimizer or sampling plan generator then converts the estimated defective die probability for each die on a wafer to a die-level sampling decision wafer map (also known as a sampling plan). The sampling plan may be generated according to input information that defines a pre-determined wafer region definition and sampling budget per wafer region, as well as user-specified sampling options. The sampling plan may provide a die-level binary sampling decision (e.g., inspect or do not inspect a die on a wafer). The sampling plan may then be used to guide an inspection tool (e.g., a scanning electron microscope, SEM, or an optical tool) to a region on the wafer where the sampling plan has a set number of dies to inspect (e.g., a sampling budget). The inspection results obtained via the sampling plan indicate a number of actual defective die present, and the inspection results may then be used to project an estimated die loss for a wafer. An R² correlation score for the defective die projection provided by the CGI model sampling plan may be determined by collecting the “ground truth” results for a wafer. The “ground truth” results indicate the actual defective die results of a wafer at the end of production and correspond to a probe test result for a fully completed wafer. Accordingly, a probe test result provides accurate identification of defects for each die on a wafer. The final metric of the CGI model and sampling plan optimizer may be the correlation R² score between the projected estimated die loss determined by the CGI model and the actual die loss determined by the probe test results.

The CGI model provides an output of a defective die probability at a die-to-die level. This means the CGI model estimates a defect probability for each die on a wafer, which may vary from die to die, and from wafer to wafer. The estimated defective die probability may be aggregated to generate a sampling plan for a wafer. Since a sampling plan may be generated for each wafer based on the specific defective die probability for each die on a wafer, the CGI model-generated sampling plan may be referred to as a “dynamic” sampling plan. The dynamic sampling plan may be used to guide inspection of a wafer to project a die loss for a wafer at the end of wafer processing.

In some embodiments of the present disclosure, the projected die loss is determined without assuming a uniform defect density or distribution within a wafer region. As described above, die loss may be projected after an inspection result is collected from an inspection tool guided by the CGI generated dynamic sampling plan. The projected die loss may be calculated via the following equations, consistent with embodiments of the present disclosure:

$$Projected die loss = \frac{{\sum }_{i = 1}^{M} ( {N}_{dd} found in CGI sampling plan \times {S}_{i} )}{{N}_{d}^{T}} \qquad ( Equation 3 )$$

$$Scaling factor , {S}_{i} = 1 + \frac{\begin{matrix}sum ( defective die probability of \\ non - sampled dies in region i )\end{matrix}}{\begin{matrix}sum ( defective die probability of \\ sampled dies in region i )\end{matrix}} \qquad ( Equation 4 )$$

In Equation 3, N_{dd} is the number of defective dies,

$${N}_{d}^{T}$$

is the total number of dies on the wafer, and Sᵢ is the scaling factor. The summation in Equation 3 is from one wafer region, i, to the total number of wafer regions, M, on a wafer. In Equation 4, the non-sampled dies are the dies not inspected according to the CGI-generated sampling plan, whereas the sampled dies are the dies that are inspected. However, each die in wafer region i has a defective die probability determined by the CGI model. Thus, the summation in the numerator in Equation 4 is equivalent to the expected number of defective dies that are not inspected, and the summation in the denominator in the Equation 4 is equivalent to the expected number of defective dies that are inspected. As the defective die probability may vary for each die in a wafer region, and in a wafer overall, the scaling factor, Sᵢ, in Equation 4 may account for non-uniform defect density distribution. The CGI model may determine the dies to inspect (e.g., sampled dies) by ranking the defective die probabilities according to a per-wafer region basis and selecting, for each wafer region, a number of dies based on the ranking of defective die probabilities. The number of dies may be less than or equal to the sampling budget for a wafer region. In other words, the CGI-generated dynamic sampling plan may combine an Nᵢ number of dies with the highest defective die probabilities, where Nᵢ is the sampling budget for wafer region i.

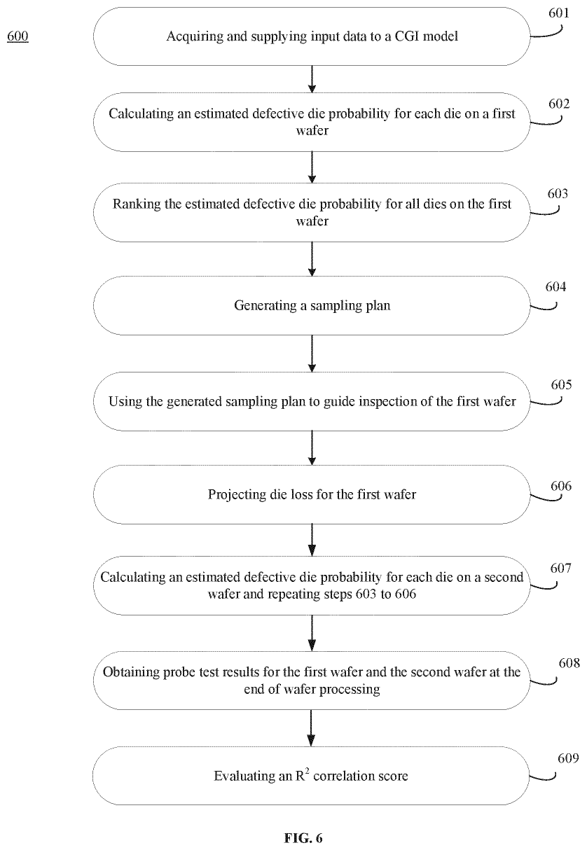

Reference is now made to FIG. 6, which is an example flow diagram of a method 600 to generate a dynamic sampling plan for a wafer and projecting die loss from an inspection result assuming non-uniform defect density or distribution within a wafer. The steps of method 600 may be performed by a computing device, e.g., processor 303 of FIG. 3. It is appreciated that the illustrated method 600 may be altered to modify the order of steps and to include additional steps.

In step 601, input data is acquired and supplied to a CGI model. The input data may correspond to an image displaying metrology information collected from a first wafer and a second wafer that are acquired via wafer processing during HVM. The wafer processing may be a lithographic focus and dose condition. The input data may include a pre-determined wafer region definition and sampling budget distribution. The metrology information may include, but is not limited to, necking, line pull back, line thinning, critical dimension, edge placement, overlapping, resist top loss, resist undercut, missing defects, and bridging defects on a wafer.

In step 602, an estimated defective die probability for each die on the first wafer is calculated based on the input data for the first wafer. The calculation may be based on identified defects in the input data and is influenced by the input data quality. The calculation may be performed by a processor (e.g., processor 303 in FIG. 3) which may apply the CGI model to the first wafer.

In step 603, the estimated defective die probabilities for all dies on the first wafer are ranked. The estimated defective die probabilities may be ranked on a per-wafer-region basis such that the top Nᵢ dies with the top Nᵢ highest estimated defective die probabilities for each wafer region are considered. As described above, Nᵢ is the sampling budget per wafer region.

In step 604, a sampling plan for the first wafer is generated based on the wafer region definition and the top Nᵢ dies for each wafer region as determined in step 603.

In step 605, the generated sampling plan for the first wafer is used to guide inspection of the first wafer using an inspection tool. The inspection tool collects inspection results of the first wafer according to the predicted defects identified by the sampling plan. In step 606, the CGI model projects die loss for the first wafer according to the inspection results collected in step 605 and according to Equations 3 and 4.

In step 607, an estimated defective die probability for each die on the second wafer is calculated based on the input data for the second wafer. The calculation may be performed by one or more processors (e.g., processor 303 in FIG. 3) that may apply the CGI model to the second wafer. The input data of the second wafer is as described above in step 601 and may include a wafer region definition for the second wafer and a sampling budget distribution. The estimated defective die probabilities for all dies on the second wafer may be ranked on a per-wafer-region basis, a sampling plan based on the ranked estimated defective die probabilities may be generated, and a die loss may be projected by repeating steps 603 to 606 but with respect to the second wafer.

In step 608, probe test results may be obtained for the first wafer and the second wafer once fully processed at the end of wafer processing. In step 609, an R² correlation score is evaluated by comparing the actual defective die result (e.g., actual die loss) for the first wafer and the second wafter to the estimated defective die probability (e.g., projected die loss) as described above.

It is appreciated that method 600 may provide a dynamic sampling plan that may guide inspection to an area on a wafer that may contain a greater concentration of possible defective dies compared to the conventional method. Moreover, method 600 may provide a more robust method to project die loss at the end stages of wafer processing. Therefore, the die loss projected by method 600 may match better with the ground truth results and the resulting R² correlation score may be increased compared to that of a conventional method.

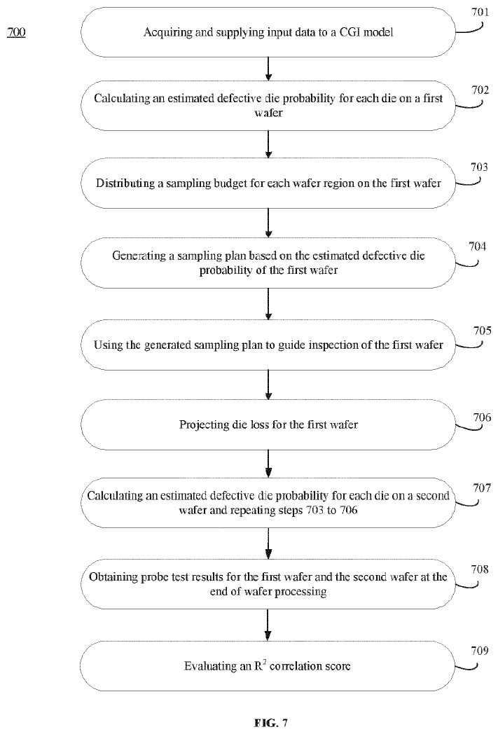

Reference is now made to FIG. 7, which is an example flow diagram of a method 700 to generate a dynamic sampling plan for a wafer without a pre-determined sampling budget distribution per wafer region, consistent with embodiments of the present disclosure. The steps of method 700 may be performed by a computing device, e.g., processor 303 of FIG. 3. It is appreciated that the illustrated method 700 may be altered to modify the order of steps and to include additional steps.

In step 701, input data is acquired and supplied to a CGI model. The input data may correspond to an image displaying metrology information collected from a first wafer and a second wafer that are acquired via wafer processing during HVM. The wafer processing may be a lithographic focus and dose condition. The input data may include a pre-determined wafer region definition. The metrology information may include, but is not limited to, necking, line pull back, line thinning, critical dimension, edge placement, overlapping, resist top loss, resist undercut, missing defects, and bridging defects on a wafer.

In step 702, an estimated defective die probability for each die on the first wafer is calculated based on the input data for the first wafer. The calculation may be based on identified defects in the input data and is influenced by the input data quality. The calculation may be performed by a processor (e.g., processor 303 in FIG. 3) which may apply the CGI model to the first wafer.

In step 703, a sampling budget for each region on the first wafer is distributed according to the estimated defective die probability for each wafer region. The calculation performed in step 703 may be as follows:

$${SB}_{i , j} = \frac{sum ( Prob . in region i )}{sum ( Prob . in full wafer )} \times {SB}_{w} \qquad ( Equation 5 )$$

$${SB}_{w} = Full wafer sampling ratio \times {N}_{d}^{w} \qquad ( Equation 6 )$$

In Equation 5, SB_{i,j} represents the sampling budget for a region i on a wafer, SB_{w} represents a full wafer sampling budget. Thus, the sampling budget for a region on a wafer may be determined by a full wafer sampling budget multiplied by the ratio of the sum of defective die probability in a wafer region to the sum of defective die probability in a full wafer. In Equation 6,

$${N}_{d}^{w}$$

represents the total number of dies per wafer. The full wafer sampling ratio is a number from 0 to 1 and represents a percentage of dies on a wafer that may be sampled for inspection.

In step 704, a sampling plan for the first wafer is generated based on the wafer region definition and the distributed sampling budget per wafer region calculated in step 703.

In step 705, the generated sampling plan for the first wafer is used to guide inspection of the first wafer using an inspection tool. The inspection tool collects inspection results of the first wafer according to the predicted defects identified by the sampling plan. In step 706, the CGI model projects die loss for the first wafer according to the inspection results collected in step 705. The die loss projection may be performed via Equations 3 and 4.

In step 707, an estimated defective die probability for each die on the second wafer is calculated based on the input data for the second wafer. The calculation may be performed by a processor (e.g., processor 303 in FIG. 3) which may apply the CGI model to the second wafer. The input data of the second wafer is as described above in step 701 and may include a wafer region definition for the second wafer and a total sampling budget. A sampling budget may be distributed for each wafer region, a sampling plan based on the estimated defective die probability may be generated, and a die loss may be projected by repeating steps 703 to 706 but with respect to the second wafer.

In step 708, probe test results may be obtained for the first wafer and the second wafer once fully processed at the end of wafer processing. In step 709, an R² correlation score is evaluated by comparing the actual defective die result (e.g., actual die loss) for the first wafer and the second wafter to the estimated defective die probability (e.g., projected die loss) as described above.

It is appreciated that method 700 may provide a sampling plan that allocates a greater percentage of the total sampling budget to a wafer region that is identified to contain a greater concentration of possible defective dies compared to the conventional method. Therefore, the estimated defective die probability map may match better with the ground truth results and the resulting R² correlation score may be increased compared to that of a conventional method.

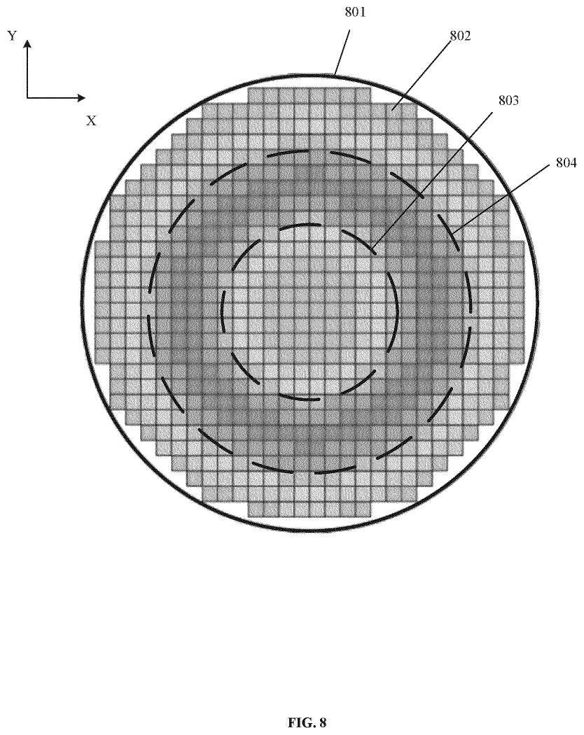

Reference is now made to FIG. 8, which is an example sampling plan or estimated defective die probability map generated by method 700, consistent with embodiments of the present disclosure. FIG. 8 corresponds to a wafer 801, which contains a die 802. Each die 802 is represented as a square on wafer 801 that is outlined in black. As described above, method 700 uses a pre-determined wafer region definition, and so the estimated defective die probability map of FIG. 8 may contain the same definition and number of wafer regions, as for example, that of FIG. 5. It is appreciated that FIG. 8 is for illustration purposes and the wafer region may be any shape or size and the wafer region number may not be so limited. FIG. 8 is represented as a gradient image, where darker color indicates a larger defective die probability and lighter color represents a lower defective die probability. Three wafer regions are illustrated in FIG. 8, where the dotted line 803 represents a first wafer region boundary between a first wafer region and a second wafer region, and the dotted line 804 represents a second wafer region boundary between the second wafer region and a third wafer region. The second wafer region (e.g., the region between dotted line 803 and dotted line 804) exhibits the darkest color and thus indicates a wafer region with the largest defective die probability. The sampling plan generated according to method 700 (FIG. 7) would allocate a greater proportion of the total sampling budget to the second region and thus guide inspection more towards the second wafer region compared to the other wafer regions. Since method 700 may optimize the sampling budget distribution per wafer region and maintain the pre-determined total sampling budget per wafer, the estimated defective die probability map of FIG. 8 may illustrate different defective die probabilities per wafer region compared to an estimated defective die probability map that may be generated for that of FIG. 5. Therefore, FIG. 8 may illustrate an improved sampling plan or more accurate die loss projection that was generated by following method 700 (in FIG. 7) to optimize a sampling budget distribution per wafer region for wafer inspection while maintaining a pre-determined wafer region definition and total sampling budget per wafer.

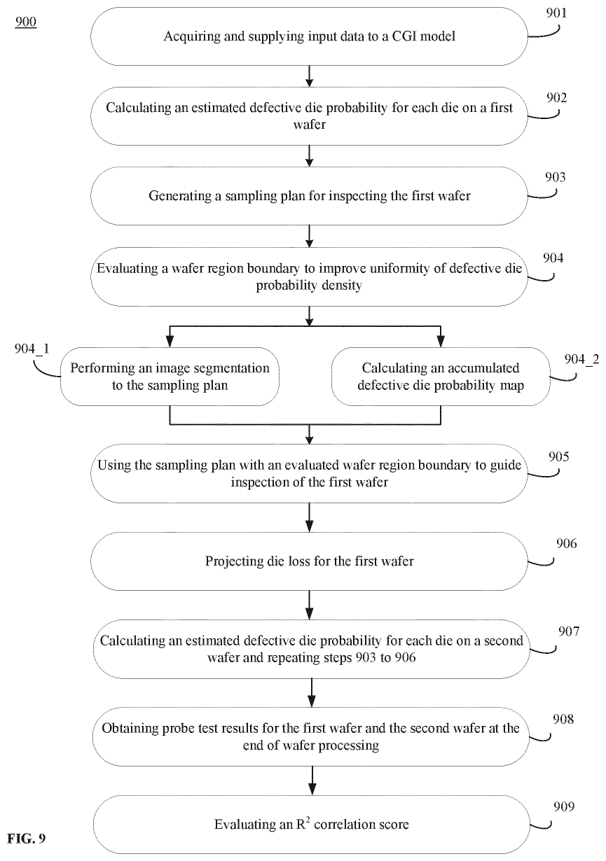

Reference is now made to FIG. 9, which is an example flow diagram of a method 900 to generate a sampling plan for a wafer without a pre-determined wafer region definition and sampling budget distribution per wafer region, consistent with embodiments of the present disclosure. The steps of method 900 may be performed by a computing device, e.g., processor 303 of FIG. 3. It is appreciated that the illustrated method 900 may be altered to modify the order of steps and to include additional steps.

In step 901, input data is acquired and supplied to a CGI model. The input data may correspond to an image displaying metrology information collected from a first wafer and a second wafer that are acquired via wafer processing during HVM. The wafer processing and metrology information may be as described above. However, the input data does not require a pre-determined wafer region definition and sampling budget distribution per wafer region.

In step 902, an estimated defective die probability for each die on the first wafer is calculated based on the input data for the first wafer. The calculation may be based on identified defects in the input data and is influenced by the input data quality. The calculation may be performed by a processor (e.g., processor 303 in FIG. 3) which may apply the CGI model to the first wafer.

In step 903, an estimated defective die probability map is generated for the first wafer by compiling the defective die probability as described above. In step 904, a boundary of a wafer region is evaluated to improve uniformity of defective die probability density on the defective die probability map. The uniformity of defective die probability density may be improved by grouping a first die on a wafer with a second die that exhibits a similar defective die probability. Step 904 may be performed in two alternative steps. Step 904_1 may be performed by applying the CGI-generated sampling plan from step 903 and performing an image segmentation technique, which may include, but is not limited to, graph cut, Otsu's algorithm, edge-based segmentation, threshold-based segmentation, region-based segmentation, cluster-based segmentation, watershed segmentation, semantic segmentation, instance segmentation, panoptic segmentation, and other methods of dividing an image into subgroups. The resulting image segmentation may define a region of dies on a wafer with improved uniformity of defective die probability density. For example, the estimated defective die probability map or sampling plan illustrated in FIG. 8 may correspond to the map or sampling plan generated in step 903. Instead of defining the wafer region boundaries as previously described, optimizing a sampling budget distribution per each defined wafer region, and thus adjusting the resulting estimated defective die probability map, step 904_1 applies a wafer region boundary to an estimated defective die probability map based on the radial distribution of defective die probabilities. Dies on a wafer may therefore be more uniformly grouped in a wafer region.

Alternatively, in step 904_2, a boundary of wafer region is determined by integrating the estimated defective die probably map with respect to radial distance to generate an accumulated defective die probability map. A wafer region boundary may be evaluated by a region of uniform slope or change in the accumulated defective die probability. Thus, an evaluated wafer region may contain dies on the wafer with similar defective die probability and improve uniformity of defective die probability density on the generated defective die probability map.

In step 905, the sampling plan with an evaluated wafer region boundary is used to guide inspection of the first wafer with an inspection tool. In step 906, the CGI model projects die loss for the first wafer according to the inspection results collected in step 905. The die loss projection may be performed via Equations 3 and 4.

In step 907, an estimated defective die probability for each die on the second wafer is calculated based on the input data for the second wafer. A sampling plan based on the estimated defective die probability may be generated, wafer regions may be evaluated, and die loss is projected for the second wafer by repeating steps 903 to 906, but with respect to the second wafer. In step 908, probe test results may be obtained for the first wafer and the second wafer once fully processed at the end of wafer processing. In step 909, an R² correlation score is evaluated by comparing the actual defective die result (e.g., actual die loss) for the first wafer and the second wafter to the estimated defective die probability (e.g., projected die loss) as described above.

It is appreciated that method 900 may provide a sampling plan that has increased versatility for different wafers. The evaluated wafer regions of method 900 may guide inspection towards an area of larger defective die probability that may have been cut off from the pre-determined and constant wafer region definition of conventional methods.

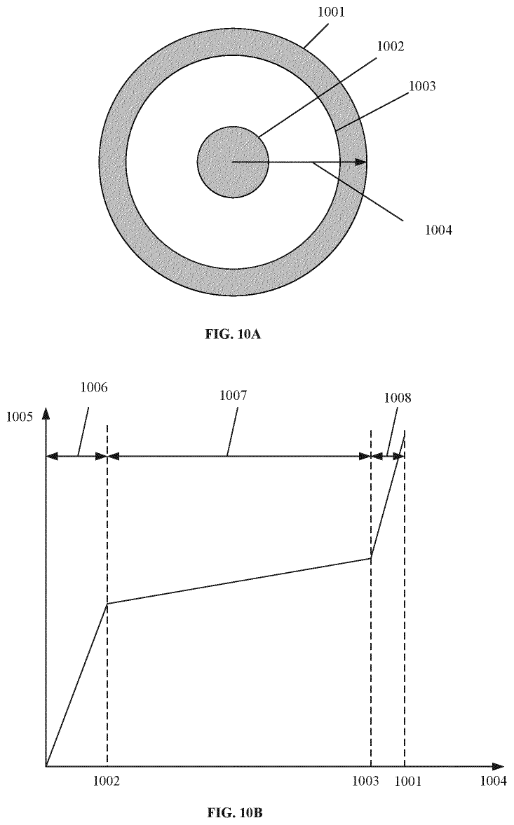

Reference is now made to FIGS. 10A and 10B, which are an example estimated defective die probability map used to evaluate a wafer region definition and an example accumulated defective die probability plot, consistent with embodiments of the present disclosure. FIG. 10A may illustrate step 903 of method 900 (see FIG. 9). As illustrated in FIG. 10A, a defective die probability map of a wafer 1001 may contain a first probability boundary 1002 and a second probability boundary 1003 which exhibit a difference in defective die probability. For example, first probability boundary 1002 illustrates a cutoff from an area of wafer 1001 where the defective die probability is higher (e.g., illustrated as gray) and an area of wafer 1001 where the defective die probability is lower (e.g., illustrated as white). The same may be observed for second probability boundary 1003. A radial distance 1004 is illustrated as starting from a center of wafer 1001, extending past first probability boundary 1002, past second probability boundary 1003, and ending at the edge of wafer 1001 (e.g., radius of wafer 1001).

Reference is now made to FIG. 10B, which is an example illustration of evaluating a wafer region definition by integrating a defective die probability map of a wafer with respect to radial distance, consistent with embodiments of the present disclosure. FIG. 10B may correspond to step 904_2 of method 900 (see FIG. 9). The plot illustrated in FIG. 10B may be obtained by integrating the defective die probability map of wafer 1001 in FIG. 10A with respect radial distance 1004. Thus FIG. 10B represents an accumulated defective die probability 1005 as a function of radial distance 1004 of wafer 1001. The dotted lines appearing from left to right, starting at the origin of FIG. 10B represent first probability boundary 1002, then second probability boundary 1003, and the edge of wafer 1001. Since radial distance 1004 begins at the center of wafer 1001, accumulated defective die probability 1005 begins at 0 and increases as radial distance 1004 increases. The radial distance between the origin and first probability boundary 1002 may correspond to a first wafer region 1006, which may correspond to the gray area enclosed by first probability boundary 1002 in FIG. 10A. The same can be observed for a second wafer region 1007 and a third wafer region 1008. First wafer region 1006 exhibits a steep slope in the plotted accumulated defective die probability since first wafer region 1006 has a greater concentration or density of defects according to FIG. 10A. The same is observed for third wafer region 1008. Since second wafer region 1007 exhibited a smaller density of defective die probability in FIG. 10A, the slope in the corresponding section in FIG. 10B is lower. The differences in slope in each region of FIG. 10B may be used to evaluate a wafer region definition for wafer 1001. In some embodiments, a wafer region may be defined such that a defective die probability density is uniform within the wafer region. For example, as illustrated in FIG. 10B, this may correspond to the slope of the plotted accumulated defective die probability remaining constant throughout a wafer region. A wafer region boundary may then be applied to the defective die probability map at the corresponding radial distance (e.g., wafer region boundary 803 and wafer region boundary 804 in FIG. 8).

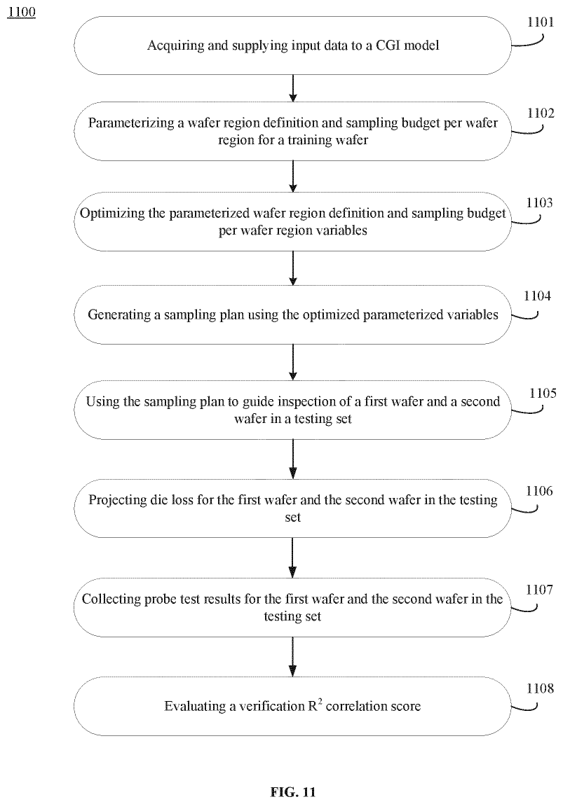

Reference is now made to FIG. 11, which is an example flow diagram of a method 1100 to directly optimize a wafer region definition and sampling budget distribution based on the die loss projection R² correlation score, consistent with embodiments of the present disclosure. Method 1100 may optimize the die loss projection R² correlation score based on a training set of wafers using parameterized wafer region definition and sampling budget per wafer region variables as optimization variables. Method 1100 may be performed after an R² correlation score is obtained for a wafer that has been inspected according to a CGI-generated sampling plan using an inspection tool and inspected via a probe test to obtain a ground truth result. Since the R² correlation score obtained for the wafer is used to guide optimization of parameterized wafer region definition and sampling budget distribution variables, the wafer may be referred to as a “training wafer.” Method 1100 may be also performed without a pre-determined wafer region definition and a sampling budget distribution per wafer region. The steps of method 1100 may be performed by a computing device, e.g., processor 303 of FIG. 3. It is appreciated that the illustrated method 1100 may be altered to modify the order of steps and to include additional steps.

In step 1101, input data is supplied to the CGI model. The input data may be a probe test result and an image for a training wafer acquired via wafer processing containing metrology information as described above.

In step 1102, a wafer region definition and sampling budget per wafer region are parameterized for the training wafer. For example, the wafer region definition may be parameterized where the wafer contains two wafer region variables. These parameterized variables may be r₁ and r₂, where r₁ is the radial distance from a center of a wafer to a first wafer region boundary and r₂ is the radial distance from the center of a wafer to a second wafer region boundary. Given this definition, r₁ is constrained to be less than r₂, and 0<r₁,r₂<rₘₐₓ, where rₘₐₓ is the maximum radial distance from the center of a wafer to the edge of the wafer. rₘₐₓ may be 150 mm. It is appreciated that a third wafer region is defined by the radial distance between r₂ and rₘₐₓ. It is further appreciated that a wafer may contain fewer or more than three wafer regions. The sampling budget per wafer region may be parameterized into variables N₁, N₂, and N₃, where N₁ corresponds to a sampling budget for a first wafer region, N₂ corresponds to a sampling budget for a second wafer region, and N₃ corresponds to a sampling budget for a third wafer region. N₁, N₂, and N₃ may be constrained such that a sampling budget for a wafer region may not exceed the total number of dies in a wafer region, and N₁+N₂+N₃=N_{budget}, where N_{budget} is the pre-determined total sampling budget for a wafer for inspection.

In step 1103, the parameterized wafer region variables and the parameterized sampling budget per wafer region variables are optimized to maximize the R² correlation score. The optimization may be performed by any constrained global optimization technique which uses a forward solver to map a parameterized wafer region variable or parameterized sampling budget per wafer region variable to a defective die loss R² correlation score based on the training wafer. A constrained global optimization technique may include, but is not limited to, Bayesian optimization, Coordinate descent, Adaptive coordinate descent, Cuckoo search, Beetle antennae search, Data-based online nonlinear extremumseeker, Evolution strategies, Genetic algorithms, Multilevel coordinate search algorithm, Nelder-Mead method, Particle swarm optimization, Pattern search, Random search, Simulated annealing, Stochastic optimization, Subgradient method, or any other derivative-free optimization algorithm. Step 1103 may be performed repeatedly until the parameterized variables described above are co-optimized to yield a maximum R² correlation score.

In step 1104, the co-optimized parameterized wafer region and sampling budget per wafer region variables are used to generate a sampling plan. In step 1105, the generated sampling plan is applied to a first wafer and a second wafer in a testing set to guide inspection of the first wafer and the second wafer in the testing set. The updated sampling plan may indicate a different wafer region definition and sampling budget distribution per wafer region compared to the sampling plan used to guide inspection for the training wafer before method 1100 is implemented.

In step 1106, the inspection result collected for the first wafer and the second wafer in the testing set is used to project die loss for the first wafer and the second in the testing set. The die loss projection may be performed via Equations 3 and 4. In step 1107, probe test results are collected for the first wafer and the second wafer in the testing set after wafer processing is completed to obtain an actual die loss. In step 1108, a verification R² correlation score is evaluated. The verification R² correlation score is compared to the starting R² correlation score of method 1100. If the verification R² correlation score is higher than the starting R² correlation score, then the co-optimized parameterized wafer region and sampling budget distribution per wafer region variables may be applied to a wafer for subsequent wafer processing.

It is appreciated that method 1100 may provide an optimization-based approach to generating an optimal fixed sampling plan setting (e.g., wafer region definition or sampling budget distribution) that has increased versatility for predicting defective die on different wafers with improved accuracy. It is further appreciated that optimized parameterized wafer region definition and sampling budget definitions determined from method 700 or method 900 may be applied as initial guesses in method 1100. This may reduce time and computational cost associated with the optimization of method 1100.

Reference is now made to Table 1, which displays R² correlation score improvements relative to the conventional method of three wafer datasets that were determined by method 600 and method 700 of the present disclosure. Specifically, each dataset comprises a batch over 100 wafers in which sampling plans were generated to guide inspection according to the method 600 and method 700 of the present disclosure. A projected die loss was calculated, and a probe test result was obtained for a fraction of wafers in the batch for Dataset 1, whereas a projected die loss was calculated, and probe test results were obtained for each wafer in Dataset 2 and Dataset 3. It is appreciated that die loss was projected using Equations 3 and 4 for both method 600 and method 700 (e.g., assuming non-uniform defect density or distribution). The R² correlation score was determined as described above, and it was found that the R² correlation score was improved for each dataset of wafers when either method 600 or method 700 was applied instead of the conventional method. The R² correlation score improvement compared to the conventional method for all three datasets when method 600 is applied indicates the benefit of assuming a non-uniform defect density or distribution in die loss projection. The R² correlation score exhibited further improvement for Dataset 2 and Dataset 3 when method 700 was applied compared to method 600. Thus, an R² correlation score may be further improved when a model-based sampling budget distribution is applied in addition to assuming a non-uniform defect density or distribution in die loss projection.

TABLE 1
Quantification of R² correlation score comparison of conventional
method to method 600 and method 700 of the present disclosure.

| | Dataset | Dataset | Dataset |
|---|---|---|---|
| Performance Metric | 1 | 2 | 3 |
| R² correlation score improvement | +50% | +17% | +61% |
| for method 600 compared to | | | |
| conventional method | | | |
| R² correlation score improvement | +48% | +23% | +78% |
| for method 700 compared to | | | |
| conventional method | | | |

A benefit provided by embodiments of the present disclosure may be an improved R² correlation score of actual die loss to projected die loss using a CGI model without required input variables. In some embodiments, the present disclosure may provide a method to project die loss without the assumption the defect density or distribution is uniform within a wafer region and improve an R² correlation score. In some embodiments, a sampling budget distribution for a wafer or a wafer region definition may be optimized to improve an R² correlation score. In some embodiments, an optimization-based model is provided that may further improve the R² correlation score. Some embodiments of the present disclosure may provide a method to improve a CGI model performance and versatility to guide wafer inspection. Some embodiments of the present disclosure may provide a method to increase defect inspection accuracy and yield of defect-free wafers throughout HVM.

A non-transitory computer readable medium may be provided that may store instructions for a processor of a controller (e.g., controller 109 of FIG. 1) to carry out, among other things, image inspection, image acquisition, stage positioning, beam focusing, electric field adjustment, beam bending, condenser lens adjusting, activating charged-particle source, beam deflecting, store instructions for a processor of a lithographic projection apparatus (e.g., lithographic projection apparatus 301 of FIG. 3) and inspection tool (e.g., inspection tool 302 of FIG. 3) to determine input data of a sample, perform method 600 of FIG. 6, perform method 700 of FIG. 7, perform method 900 of FIG. 9, perform method 1100 of FIG. 1100, and other executable functions relating to modeling and optimizing a wafer region definition or sampling budget distribution per wafer region for inspection during HVM. Common forms of non-transitory media include, for example, a floppy disk, a flexible disk, hard disk, solid state drive, magnetic tape, or any other magnetic data storage medium, a Compact Disc Read Only Memory (CD-ROM), any other optical data storage medium, any physical medium with patterns of holes, a Random Access Memory (RAM), a Programmable Read Only Memory (PROM), and Erasable Programmable Read Only Memory (EPROM), a FLASH-EPROM or any other flash memory, Non-Volatile Random Access Memory (NVRAM), a cache, a register, any other memory chip or cartridge, and networked versions of the same.

The embodiments may further be described using the following clauses:
1. A method to generate an inspection tool sampling plan, the method comprising:
providing input data for a wafer to a computational defect probability prediction model; dividing the wafer into a plurality of wafer regions having dies;
determining defective die probabilities per wafer region from the computational defect probability prediction model;
selecting at least one die from each wafer region of the plurality of wafer regions using the determined defective die probabilities; and
generating a sampling plan for the wafer based on the selected dies.
2. The method of clause 1, wherein the input data comprises an image containing metrology information of the wafer.
3. The method of clause 1 or 2, wherein the input data comprises a pre-determined wafer region definition and a sampling budget for each wafer region.
4. The method of clause 3, wherein selecting at least one die from each wafer region of the plurality of wafer regions using the determined defective die probabilities further comprises:
ranking the determined defective die probabilities per wafer region; and
selecting, for each wafer region of the plurality of wafer regions, a number of dies based on the ranking of determined defective die probabilities, wherein the number of dies is less than or equal to the sampling budget for the respective wafer region.
5. The method of any one of clauses 1 to 4, further comprising:
using the sampling plan to guide wafer inspection of the wafer;
calculating a projected die loss using an inspection result of the wafer;
obtaining a probe test result for the wafer; and
evaluating an R² correlation score by comparing the probe test result to the projected die loss.
6. The method of clause 5, wherein the projected die loss is calculated by assuming a non-uniform defect density or distribution in the wafer.
7. The method of any one of clauses 1 to 6, wherein the inspection tool is a scanning charged particle microscope or an optical tool.
8. The method of any one of clauses 1 to 7, wherein the computational defect probability prediction model is a computational guided inspection model.
9. A method to optimize an inspection tool sampling plan, the method comprising:
providing input data for a wafer to a computational defect probability prediction model; and distributing a sampling budget for a region of a wafer based on an expected number of defective die count for the region compared to an expected number of defective die count for the wafer;
wherein the expected number of defective die count for the region is a summation of predicted defective die probability for the region and the expected number of defective die count for the wafer is a summation of predicted defective die probability for the wafer; and
wherein the predicted defective die probability for the region and the predicted defective die probability for the wafer are obtained from the computational defect probability prediction model.
10. The method of clause 9, wherein the input data comprises an image containing metrology information of the wafer.
11. The method of clause 9 or 10, wherein the input data comprises a pre-determined wafer region definition and sampling budget for the wafer.
12. The method of any one of clauses 9 to 11, further comprising:
generating a sampling plan to guide wafer inspection of the wafer;
calculating a projected die loss using an inspection result of the wafer;
obtaining a probe test result for the wafer; and
evaluating an R² correlation score by comparing the probe test result to the projected die loss.
13. The method of any one of clauses 9 to 12, wherein the inspection tool is a scanning charged particle microscope or an optical tool.
14. The method of any one of clauses 9 to 13, wherein the computational defect probability prediction model is a computational guided inspection model.
15. A method to optimize an inspection tool sampling plan, the method comprising:
providing input data for a wafer to a computational defect probability prediction model;
determining a defective die probability for each die of the wafer from the computational defect probability prediction model;
generating a sampling plan;
evaluating a wafer region from the defective die probability for each die of the wafer;
evaluating a sampling budget distribution for each evaluated wafer region; and
using the sampling plan with the evaluated wafer region and sampling budget distribution to guide wafer inspection of the wafer.
16. The method of clause 15, wherein the input data comprises an image containing metrology information of the wafer.
17. The method of clause 15 or 16, wherein the input data comprises a pre-determined sampling budget for the wafer.
18. The method of any one of clauses 15 to 17, wherein the wafer region is evaluated by integrating the calculated defective die probability for each die of the wafer with respect to a radial direction on the wafer.
19. The method of any one of clauses 15 to 17, wherein the wafer region is evaluated by image segmentation of the calculated defective die probability for each die of the wafer.
20. The method of any one of clauses 15 to 19, further comprising:
calculating a projected die loss using an inspection result of the wafer;
obtaining a probe test result for the wafer; and
evaluating an R² correlation score by comparing the probe test result to the projected die loss.
21. The method of any one of clauses 15 to 20, wherein the inspection tool is a scanning charged particle microscope or an optical tool.
22. The method of any one of clauses 15 to 21, wherein the computational defect probability prediction model is a computational guided inspection model.
23. A method of optimizing an inspection tool sampling plan, the method comprising:
providing input data for a wafer to a computational defect probability prediction model;
parameterizing a wafer region definition and a sampling budget for a wafer region, wherein the parameterized wafer region definition and sampling budget for the wafer region have certain constraints; and
optimizing the parameterized wafer region definition and the parameterized sampling budget for the wafer region according to the certain constraints to maximize a projected value.
24. The method of clause 23, wherein the input data comprises a probe test result of the wafer.
25. The method of clause 23 or 24, wherein the input data comprises an R² correlation score.
26. The method of any one of clauses 23 to 25, wherein the wafer region definition is parameterized using a first variable and a second variable.
27. The method of clause 26, wherein the first variable is r₁ and the second variable is r₂, wherein r₁ is a radial distance from a center of the wafer to a first wafer region boundary, and wherein r₂ is a radial distance from the center of the wafer to a second wafer region boundary.
28. The method of clause 27, wherein a constraint for the first variable and the second variable comprises 0<r₁, r₂<rₘₐₓ, wherein rₘₐₓ is a radius of the wafer.
29. The method of clause 27 or 28, wherein the constraint for the first variable and the second variable comprises r₁<r₂.
30. The method of any one of clauses 23 to 29, wherein the sampling budget for a wafer region on the wafer is parameterized using a first variable, a second variable, and a third variable.
31. The method of clause 30, wherein the first variable is N₁, the second variable is N₂, and the third variable is N₃, wherein N₁ is a sampling budget for a first wafer region, wherein N₂ is a sampling budget for a second wafer region, and wherein N₃ is a sampling budget for a third wafer region.
32. The method of clause 31, wherein a constraint for N₁, N₂, and N₃ comprises N₁+N₂+N₃=N_{budget}, wherein N_{budget} is a total sampling budget for the wafer.
33. The method of clause 31 or 32, wherein N₁, N₂, and N₃ are less than a total number of dies in the first wafer region, the second wafer region, and the third wafer region, respectively.
34. The method of any one of clauses 23 to 33, wherein optimizing the parameterized wafer region definition and the parameterized sampling budget for the wafer region comprises using a constrained global optimization technique.
35. The method of clause 34, wherein the constrained global optimization technique is a derivative-free optimization algorithm.
36. The method of any one of clauses 23 to 35, wherein the projected value is an R² correlation score generated by optimizing the parameterized wafer region definition and the parameterized sampling budget for the wafer region.
37. The method of any one of clauses 23 to 36, further comprising:
generating a sampling plan to guide wafer inspection of a second wafer;
calculating a projected die loss using an inspection result of the second wafer;
obtaining a probe test result for the second wafer; and
evaluating a R² correlation score.
38. The method of any one of clauses 23 to 37, wherein the inspection tool is a scanning charged particle microscope or an optical tool.
39. The method of any one of clauses 23 to 38, wherein the computational defect probability prediction model is a computational guided inspection model.
40. An apparatus to generate an inspection tool sampling plan, comprising:
a memory storing a set of instructions; and
at least one processor configured to execute the set of instructions to cause the apparatus to perform operations comprising
providing input data for a wafer to a computational defect probability prediction model;
dividing the wafer into a plurality of wafer regions having dies;
determining defective die probabilities per wafer region from the computational defect probability prediction model;
selecting at least one die from each wafer region of the plurality of wafer regions using the determined defective die probabilities; and
generating a sampling plan for the wafer based on the selected dies.
41. The apparatus of clause 40, wherein the input data comprises an image containing metrology information of the wafer.
42. The apparatus of clause 40 or 41, wherein the input data comprises a pre-determined wafer region definition and a sampling budget for each wafer region.
43. The apparatus of clause 42, wherein selecting at least one die from each wafer region of the plurality of wafer regions using the determined defective die probabilities further comprises:
ranking the determined defective die probability for each die per wafer region; and
selecting, for each wafer region of the plurality of wafer regions, a number of dies based on the ranking of determined defective die probabilities, wherein the number of dies is less than or equal to the sampling budget for the respective wafer region.
44. The apparatus of any one of clauses 40 to 43, wherein the operations further comprise:
using the sampling plan to guide wafer inspection of the wafer;
calculating a projected die loss using an inspection result of the wafer;
obtaining a probe test result for the wafer; and
evaluating an R² correlation score by comparing the probe test result to the projected die loss.
45. The apparatus of clause 44, wherein the projected die loss is calculated by assuming a non-uniform defect density or distribution in the wafer.
46. The apparatus of any one of clauses 40 to 45, wherein the inspection tool is a scanning charged particle microscope or an optical tool.
47. The apparatus of any one of clauses 40 to 46, wherein the computational defect probability prediction model is a computational guided inspection model.
48. An apparatus for optimizing an inspection tool sampling plan, comprising:
a memory storing a set of instructions; and
at least one processor configured to execute the set of instructions to cause the apparatus to perform operations comprising:
providing input data for a wafer to a computational defect probability prediction model; and
distributing a sampling budget for a region of a wafer based on an expected number of defective die count for the region compared to an expected number of defective die count for the wafer;
wherein the expected number of defective die count for the region is a summation of predicted defective die probability for the region and the expected number of defective die count for the wafer is a summation of predicted defective die probability for the wafer; and
wherein the predicted defective die probability for the region and the predicted defective die probability for the wafer are obtained from the computational defect probability prediction model.
49. The apparatus of clause 48, wherein the input data comprises an image containing metrology information of the wafer.
50. The apparatus of clause 48 or 49, wherein the input data comprises a pre-determined wafer region definition and sampling budget for the wafer.
51. The apparatus of any one of clauses 48 to 50, wherein the operations further comprise:
generating a sampling plan to guide wafer inspection of the wafer;
calculating a projected die loss using an inspection result of the wafer;
obtaining a probe test result for the wafer; and
evaluating an R² correlation score by comparing the probe test result to the projected die loss.
52. The apparatus of any one of clauses 48 to 51, wherein the inspection tool is a scanning charged particle microscope or an optical tool.
53. The apparatus of any one of clauses 48 to 52, wherein the computational defect probability prediction model is a computational guided inspection model.
54. An apparatus for optimizing an inspection tool sampling plan, comprising:
a memory storing a set of instructions; and
at least one processor configured to execute the set of instructions to cause the apparatus to perform operations comprising:
providing input data for a wafer to a computational defect probability prediction model;
determining a defective die probability for each die of the wafer from the computational defect probability prediction model;
generating a sampling plan;
evaluating a wafer region from the defective die probability for each die of the wafer;
evaluating a sampling budget distribution for each evaluated wafer region; and
using the sampling plan with the evaluated wafer region and sampling budget distribution to guide wafer inspection of the wafer.
55. The apparatus of clause 54, wherein the input data comprises an image containing metrology information of the wafer.
56. The apparatus of clause 54 or 55, wherein the input data comprises a pre-determined sampling budget for the wafer.
57. The apparatus of any one of clauses 54 to 56, wherein the wafer region is evaluated by integrating the calculated defective die probability for each die of the wafer with respect to a radial direction on the wafer.
58. The apparatus of any one of clauses 54 to 56, wherein the wafer region is evaluated by image segmentation of the generated defective die probability map of the wafer.
59. The apparatus of any one of clauses 54 to 58, wherein the operations further comprise: calculating a projected die loss using an inspection result of the wafer;
obtaining a probe test result for the wafer; and
evaluating an R² correlation score by comparing the probe test result to the projected die loss.
60. The apparatus of any one of clauses 54 to 59, wherein the inspection tool is a scanning charged particle microscope or an optical tool.
61. The apparatus of any one of clauses 54 to 60, wherein the computational defect probability prediction model is a computational guided inspection model.
62. An apparatus for optimizing an inspection tool sampling plan, comprising:
a memory storing a set of instructions; and
at least one processor configured to execute the set of instructions to cause the apparatus to perform operations comprising:
providing input data for a wafer to a computational defect probability prediction model;
parameterizing a wafer region definition and a sampling budget for a wafer region, wherein the parameterized wafer region definition and sampling budget for the wafer region have certain constraints; and
optimizing the parameterized wafer region definition and the parameterized sampling budget for the wafer region according to the certain constraints to maximize a projected value.
63. The apparatus of clause 62, wherein the input data comprises a probe test result of the wafer.
64. The apparatus of clause 62 or 63, wherein the input data comprises an R² correlation score.
65. The apparatus of any one of clauses 62 to 64, wherein the wafer region definition is parameterized using a first variable and a second variable.
66. The apparatus of clause 65, wherein the first variable is r₁ and the second variable is r₂, wherein r₁ is a radial distance from a center of the wafer to a first wafer region boundary, and wherein r₂ is a radial distance from the center of the wafer to a second wafer region boundary.
67. The apparatus of clause 66, wherein a constraint for the first variable and the second variable comprises 0<r₁, r₂<rₘₐₓ, wherein rₘₐₓ is a radius of the wafer.
68. The apparatus of clause 66 or 67, wherein the constraint for the first variable and the second variable comprises r₁<r₂.
69. The apparatus of any one of clauses 62 to 68, wherein the sampling budget for a wafer region on the wafer is parameterized using a first variable, a second variable, and a third variable.
70. The apparatus of clause 69, wherein the first variable is N₁, the second variable is N₂, and the third variable is N₃, wherein N₁ is a sampling budget for a first wafer region, wherein N₂ is a sampling budget for a second wafer region, and wherein N₃ is a sampling budget for a third wafer region.
71. The apparatus of clause 70, wherein a constraint for N₁, N₂, and N₃ comprises N₁+N₂+N₃=N_{budget}, wherein N_{budget} is a total sampling budget for the wafer.
72. The apparatus of clause 70 or 71, wherein N₁, N₂, and N₃ are less than a total number of dies in the first wafer region, the second wafer region, and the third wafer region, respectively.
73. The apparatus of any one of clauses 62 to 72, wherein optimizing the parameterized wafer region definition and the parameterized sampling budget for the wafer region comprises using a constrained global optimization technique.
74. The apparatus of clause 73, wherein the constrained global optimization technique is a derivative-free optimization algorithm.
75. The apparatus of any one of clauses 62 to 74, wherein the projected value is an R² correlation score generated by optimizing the parameterized wafer region definition and the parameterized sampling budget for the wafer region.
76. The apparatus of any one of clauses 62 to 75, wherein the operations further comprise:
generating a sampling plan to guide wafer inspection of a second wafer;
calculating a projected die loss using an inspection result of the second wafer;
obtaining a probe test result for the second wafer; and
evaluating an R² correlation score.
77. The apparatus of any one of clauses 62 to 76, wherein the inspection tool is a scanning charged particle microscope or an optical tool.
78. The apparatus of any one of clauses 62 to 77, wherein the computational defect probability prediction model is a computational guided inspection model.
79. A non-transitory computer readable medium comprising a set of instructions that is executable by one or more processors of a computing device to cause the computing device to perform operations for generating an inspection tool sampling plan, the operations comprising:
providing input data for a wafer to a computational defect probability prediction model;
dividing the wafer into a plurality of wafer regions having dies;
determining defective die probabilities per wafer region from the computational defect probability prediction model;
selecting at least one die from each wafer region of the plurality of wafer regions using the determined defective die probabilities; and
generating a sampling plan for the wafer based on the selected dies.
80. The non-transitory computer readable medium of clause 79, wherein the input data comprises an image containing metrology information of the wafer.
81. The non-transitory computer readable medium of clause 79 or 80, wherein the input data comprises a pre-determined wafer region definition and a sampling budget for each wafer region.
82. The non-transitory computer readable medium of clause 81, wherein selecting at least one die from each wafer region of the plurality of wafer regions using the determined defective die probabilities further comprises:
ranking the determined defective die probability for each die per wafer region; and
selecting, for each wafer region of the plurality of wafer regions, a number of dies based on the ranking of determined defective die probabilities, wherein the number of dies is less than or equal to the sampling budget for the respective wafer region.
83. The non-transitory computer readable medium of any one of clauses 79 to 82, wherein the operations further comprise:
using the sampling plan to guide wafer inspection of the wafer;
calculating a projected die loss using an inspection result of the wafer;
obtaining a probe test result for the wafer; and
evaluating an R² correlation score by comparing the probe test result to the projected die loss.
84. The non-transitory computer readable medium of clause 83, wherein the projected die loss is calculated by assuming a non-uniform defect density or distribution in the wafer.
85. The non-transitory computer readable medium of any one of clauses 79 to 82, wherein the inspection tool is a scanning charged particle microscope or an optical tool.
86. The non-transitory computer readable medium of any one of clauses 79 to 85, wherein the computational defect probability prediction model is a computational guided inspection model.
87. A non-transitory computer readable medium comprising a set of instructions that is executable by one or more processors of a computing device to cause the computing device to perform operations for optimizing an inspection tool sampling plan, the operations comprising:
providing input data for a wafer to a computational defect probability prediction model; and
distributing a sampling budget for a region of a wafer based on an expected number of defective die count for the region compared to an expected number of defective die count for the wafer;
wherein the expected number of defective die count for the region is a summation of predicted defective die probability for the region and the expected number of defective die count for the wafer is a summation of predicted defective die probability for the wafer; and
wherein the predicted defective die probability for the region and the predicted defective die probability for the wafer are obtained from the computational defect probability prediction model.
88. The non-transitory computer readable medium of clause 87, wherein the input data comprises an image containing metrology information of the wafer.
89. The non-transitory computer readable medium of clause 87 or 88, wherein the input data comprises a pre-determined wafer region definition and sampling budget for the wafer.
90. The non-transitory computer readable medium of any one of clauses 87 to 89, wherein the operations further comprise:
generating a sampling plan to guide wafer inspection of the wafer;
calculating a projected die loss using an inspection result of the wafer;
obtaining a probe test result for the wafer; and
evaluating an R² correlation score by comparing the probe test result to the projected die loss.
91. The non-transitory computer readable medium of any one of clauses 87 to 90, wherein the inspection tool is a scanning charged particle microscope or an optical tool.
92. The non-transitory computer readable medium of any one of clauses 87 to 91, wherein the computational defect probability prediction model is a computational guided inspection model.
93. A non-transitory computer readable medium comprising a set of instructions that is executable by one or more processors of a computing device to cause the computing device to perform operations for optimizing an inspection tool sampling plan, the operations comprising:
providing input data for a wafer to a computational defect probability prediction model;
determining a defective die probability for each die of the wafer from the computational defect probability prediction model;
generating a sampling plan;
evaluating a wafer region from the defective die probability for each die of the wafer;
evaluating a sampling budget distribution for each evaluated wafer region; and
using the sampling plan with the evaluated wafer region and evaluated sampling budget distribution to guide wafer inspection of the wafer.
94. The non-transitory computer readable medium of clause 93, wherein the input data comprises an image containing metrology information of the wafer.
95. The non-transitory computer readable medium of clause 93 or 94, wherein the input data comprises a pre-determined sampling budget for the wafer.
96. The non-transitory computer readable medium of any one of clauses 93 to 95, wherein the wafer region is evaluated by integrating the calculated defective die probability for each die of the wafer with respect to a radial direction on the wafer.
97. The non-transitory computer readable medium of any one of clauses 93 to 95, wherein the wafer region is evaluated by image segmentation of the generated defective die probability map of the wafer.
98. The non-transitory computer readable medium of any one of clauses 93 to 97, wherein the operations further comprise:
calculating a projected die loss using an inspection result of the wafer;
obtaining a probe test result for the wafer; and
evaluating an R² correlation score by comparing the probe test result to the projected die loss.
99. The non-transitory computer readable medium of any one of clauses 93 to 98, wherein the inspection tool is a scanning charged particle microscope or an optical tool.
100. The non-transitory computer readable medium of any one of clauses 93 to 99, wherein the computational defect probability prediction model is a computational guided inspection model.
101. A non-transitory computer readable medium comprising a set of instructions that is executable by one or more processors of a computing device to cause the computing device to perform operations for optimizing an inspection tool sampling plan, the operations comprising:
providing input data for a wafer to a computational defect probability prediction model;
parameterizing a wafer region definition and a sampling budget for a wafer region, wherein the parameterized wafer region definition and sampling budget for the wafer region have certain constraints; and
optimizing the parameterized wafer region definition and the parameterized sampling budget for the wafer region according to the certain constraints to maximize a projected value.
102. The non-transitory computer readable medium of clause 101, wherein the input data comprises a probe test result of the wafer.
103. The non-transitory computer readable medium of clause 101 or 102, wherein the input data comprises an R² correlation score.
104. The non-transitory computer readable medium of any one of clauses 101 to 103, wherein the wafer region definition is parameterized using a first variable and a second variable.
105. The non-transitory computer readable medium of clause 104, wherein the first variable is r₁ and the second variable is r₂, wherein r₁ is a radial distance from a center of the wafer to a first wafer region boundary, and wherein r₂ is a radial distance from the center of the wafer to a second wafer region boundary.
106. The non-transitory computer readable medium of clause 105, wherein a constraint for the first variable and the second variable comprises 0<r₁, r₂<rₘₐₓ, wherein rₘₐₓ is a radius of the wafer.
107. The non-transitory computer readable medium of clause 105 or 106, wherein the constraint for the first variable and the second variable comprises r₁<r₂.
108. The non-transitory computer readable medium of any one of clauses 101 to 107, wherein the sampling budget for a wafer region on the wafer is parameterized using a first variable, a second variable, and a third variable.
109. The non-transitory computer readable medium of clause 108, wherein the first variable is Nᵢ, the second variable is N₂, and the third variable is N₃, wherein N₁ is a sampling budget for a first wafer region, wherein N₂ is a sampling budget for a second wafer region, and wherein N₃ is a sampling budget for a third wafer region.
110. The non-transitory computer readable medium of clause 109, wherein a constraint for N₁, N₂, and N₃ comprises N₁+N₂+N₃=N_{budget}, wherein N_{budget} is a total sampling budget for the wafer.
111. The non-transitory computer readable medium of clause 109 or 110, wherein N₁, N₂, and N₃ are less than a total number of dies in the first wafer region, the second wafer region, and the third wafer region, respectively.
112. The non-transitory computer readable medium of any one of clauses 101 to 111, wherein optimizing the parameterized wafer region definition and the parameterized sampling budget for the wafer region comprises using a constrained global optimization technique.
113. The non-transitory computer readable medium of clause 112, wherein the constrained global optimization technique is a derivative-free optimization algorithm.
114. The non-transitory computer readable medium of any one of clauses 101 to 113, wherein the projected value is an R² correlation score generated by optimizing the parameterized wafer region definition and the parameterized sampling budget for the wafer region.
115. The non-transitory computer readable medium of any one of clauses 101 to 114, wherein the operations further comprise:
generating a sampling plan to guide wafer inspection of a second wafer;
calculating a projected die loss using an inspection result of the second wafer;
obtaining a probe test result for the second wafer; and
evaluating an R² correlation score.
116. The non-transitory computer readable medium of any one of clauses 101 to 115, wherein the inspection tool is a scanning charged particle microscope or an optical tool.
117. The non-transitory computer readable medium of any one of clauses 101 to 116, wherein the computational defect probability prediction model is a computational guided inspection model.
118. A system using a computational model to generate an inspection tool sampling plan, the system comprising:
one or more processors configured to execute instructions to cause the system to perform:
providing input data for a wafer to a computational defect probability prediction model;
dividing the wafer into a plurality of wafer regions having dies;
determining defective die probabilities per wafer region from the computational defect probability prediction model;
selecting at least one die from each wafer region of the plurality of wafer regions using the determined defective die probabilities; and
generating a sampling plan for the wafer based on the selected dies.

Block diagrams in the figures may illustrate the architecture, functionality, and operation of possible implementations of systems, methods, and computer hardware or software products according to various exemplary embodiments of the present disclosure. In this regard, each block in a schematic diagram may represent certain arithmetical or logical operation processing that may be implemented using hardware such as an electronic circuit. Blocks may also represent a module, segment, or portion of code that comprises one or more executable instructions for implementing the specified logical functions. It should be understood that in some alternative implementations, functions indicated in a block may occur out of the order noted in the figures. For example, two blocks shown in succession may be executed or implemented substantially concurrently, or two blocks may sometimes be executed in reverse order, depending upon the functionality involved. Some blocks may also be omitted. It should also be understood that each block of the block diagrams, and combination of the blocks, may be implemented by special purpose hardware-based systems that perform the specified functions or acts, or by combinations of special purpose hardware and computer instructions.

It will be appreciated that the embodiments of the present disclosure are not limited to the exact construction that has been described above and illustrated in the accompanying drawings, and that various modifications and changes may be made without departing from the scope thereof. The present disclosure has been described in connection with various embodiments, and other embodiments will be apparent to those skilled in the art from consideration of the specification and practice of the technology disclosed herein. It is intended that the specification and examples be considered as exemplary only, with a true scope and spirit of the disclosure being indicated by the following claims.

1. An apparatus to generate an inspection tool sampling plan, comprising:
a memory storing a set of instructions; and
at least one processor configured to execute the set of instructions to cause the apparatus to perform operations comprising
providing input data for a wafer to a computational defect probability prediction model;
dividing the wafer into a plurality of wafer regions having dies;
determining defective die probabilities per wafer region from the computational defect probability prediction model;
selecting at least one die from each wafer region of the plurality of wafer regions using the determined defective die probabilities; and
generating a sampling plan for the wafer based on the selected dies.

2. The apparatus of claim 1, wherein the input data comprises an image containing metrology information of the wafer.

3. The apparatus of claim 1, wherein the input data comprises a pre-determined wafer region definition and a sampling budget for each wafer region.

4. The apparatus of claim 3, wherein selecting at least one die from each wafer region of the plurality of wafer regions using the determined defective die probabilities further comprises:
ranking the determined defective die probability for each die per wafer region; and
selecting, for each wafer region of the plurality of wafer regions, a number of dies based on the ranking of determined defective die probabilities, wherein the number of dies is less than or equal to the sampling budget for the respective wafer region.

5. The apparatus of claim 1, wherein the operations further comprise:
using the sampling plan to guide wafer inspection of the wafer;
calculating a projected die loss using an inspection result of the wafer;
obtaining a probe test result for the wafer; and
evaluating an R² correlation score by comparing the probe test result to the projected die loss.

6. The apparatus of claim 5, wherein the projected die loss is calculated by assuming a non-uniform defect density or distribution in the wafer.

7. The apparatus of claim 1, wherein the inspection tool is a scanning charged particle microscope or an optical tool.

8. The apparatus of claim 1, wherein the computational defect probability prediction model is a computational guided inspection model.

9. An apparatus for optimizing an inspection tool sampling plan, comprising:
a memory storing a set of instructions; and
at least one processor configured to execute the set of instructions to cause the apparatus to perform operations comprising:
providing input data for a wafer to a computational defect probability prediction model; and
distributing a sampling budget for a region of a wafer based on an expected number of defective die count for the region compared to an expected number of defective die count for the wafer;
wherein the expected number of defective die count for the region is a summation of predicted defective die probability for the region and the expected number of defective die count for the wafer is a summation of predicted defective die probability for the wafer; and
wherein the predicted defective die probability for the region and the predicted defective die probability for the wafer are obtained from the computational defect probability prediction model.

10. The apparatus of claim 9, wherein the input data comprises an image containing metrology information of the wafer.

11. The apparatus of claim 9, wherein the input data comprises a pre-determined wafer region definition and sampling budget for the wafer.

12. The apparatus of claim 9, wherein the operations further comprise:
generating a sampling plan to guide wafer inspection of the wafer;
calculating a projected die loss using an inspection result of the wafer;
obtaining a probe test result for the wafer; and
evaluating an R² correlation score by comparing the probe test result to the projected die loss.

13. The apparatus of claim 9, wherein the inspection tool is a scanning charged particle microscope or an optical tool.

14. The apparatus of claim 9, wherein the computational defect probability prediction model is a computational guided inspection model.

15. An apparatus for optimizing an inspection tool sampling plan, comprising:
a memory storing a set of instructions; and
at least one processor configured to execute the set of instructions to cause the apparatus to perform operations comprising:
providing input data for a wafer to a computational defect probability prediction model;
determining a defective die probability for each die of the wafer from the computational defect probability prediction model;
generating a sampling plan;
evaluating a wafer region from the defective die probability for each die of the wafer;
evaluating a sampling budget distribution for each evaluated wafer region; and
using the sampling plan with the evaluated wafer region and sampling budget distribution to guide wafer inspection of the wafer.

16. The apparatus of claim 15, wherein the input data comprises an image containing metrology information of the wafer.

17. The apparatus of claim 15, wherein the input data comprises a pre-determined sampling budget for the wafer.

18. The apparatus of claim 15, wherein the wafer region is evaluated by integrating the determined defective die probability for each die of the wafer with respect to a radial direction on the wafer.

19. The apparatus of claim 15, wherein the wafer region is evaluated by image segmentation of the generated defective die probability map of the wafer.

20. The apparatus of claim 15, wherein the operations further comprise:
calculating a projected die loss using an inspection result of the wafer;
obtaining a probe test result for the wafer; and
evaluating an R2 correlation score by comparing the probe test result to the projected die loss.
